(19) United States
(12) Patent Application Publication
(10) Pub. No.: US 2016/0149159 A1
(43) Pub. Date: May 26, 2016

(54) GAS BARRIER FILM AND ELECTRONIC DEVICE

(71) Applicant: KONICA MINOLTA, INC., Tokyo (JP)

(72) Inventor: Takahiro MORI, Tokyo (JP)

(21) Appl. No.: 14/903,094

(22) PCT Filed: Jul. 2, 2014
(86) PCT No.: PCT/JP2014/067702

§ 371 Date: Jan. 6, 2016

(30) Foreign Application Priority Data
Jul. 8, 2013 (JP) 2013-143025

(51) Int. Cl. H01L 51/52; C09D 5/00; C09D 7/12

(52) U.S. Cl. CPC H01L 51/5253; C09D 7/1233; C09D 5/00

(57) ABSTRACT

The present invention provides a gas barrier film having high gas barrier properties and also having high durability even under harsh, high-temperature, high-humidity conditions. The gas barrier film includes a substrate and at least one gas barrier layer on the substrate, wherein the gas barrier layer includes at least one gas barrier layer A having a chemical composition of chemical formula (1): SiAl_{w}OₓN_{y}C_{z}, wherein w, x, y, and z are the elemental ratios of aluminum to silicon, oxygen to silicon, nitrogen to silicon, and carbon to silicon, respectively, measured in the thickness direction of the gas barrier layer, y is the maximum value of the elemental ratio of nitrogen to silicon measured in the thickness direction of the gas barrier layer and satisfies mathematical formula (1): 0.05≦y≦0.20, and w, x, and z satisfy mathematical formula (2): 0.07≦w≦0.20, mathematical formula (3): 1.90≦x≦2.40, and mathematical formula (4): 0.00≦z≦0.20, respectively, when measured at the point where the elemental ratio of nitrogen to silicon is the maximum value.

### TECHNICAL FIELD

The present invention relates to a gas barrier film and an electronic device. More specifically, the present invention relates to a gas barrier film having high gas barrier properties and still having high gas barrier properties even after storage under harsh, high-temperature, high-humidity conditions, and to an electronic device having such a gas barrier film.

### BACKGROUND ART

Conventional gas barrier films are formed by stacking, on the surface of a plastic substrate or film, a plurality of layers including a thin film of a metal oxide such as aluminum oxide, magnesium oxide, or silicon oxide. Such gas barrier films are widely used to form packages for products from which various gases such as water vapor and oxygen need to be blocked. For example, such gas barrier films are widely used for package applications for preventing the degradation of foods, industrial products, pharmaceuticals, and other products.

Besides package applications, gas barrier films are desired to be used for flexible electronic devices such as flexible photovoltaic cell devices, organic electroluminescence (EL) devices, and liquid crystal display devices, and many studies have been conducted. Unfortunately, gas barrier films having sufficient performance for such flexible electronic devices are not available at present, because very high gas barrier properties and durability equivalent to those of a glass substrate are required for such electronic devices.

Known methods for forming the gas barrier films mentioned above include gas phase methods such as chemical vapor deposition or plasma CVD, in which a film is deposited on a substrate using an organosilicon compound such as tetraethoxysilane (TEOS) while the compound is oxidized with an oxygen plasma under reduced pressure, and physical deposition techniques (vacuum deposition and sputtering), in which metallic Si is evaporated with a semiconductor laser and deposited on a substrate in the presence of oxygen.

These gas phase methods can form an inorganic thin film with a precise composition on a substrate. Therefore, many studies have been conducted to form inorganic films with a variety of compositions, such as silicon oxide films, silicon nitride films, aluminum oxide films, and films of a complex oxide composed of silicon oxide and aluminum oxide.

For example, JP 06-337406 A discloses that in order to ensure gas barrier properties and a reduction in thickness and weight, an SiAlON film formed by sputtering is provided, which is an inorganic film having high barrier properties per unit thickness as compared with a silicon oxide film or a silicon nitride film.

JP 2009-220343 A discloses that in order to ensure gas barrier properties and flexibility, a gas barrier film has an SiAlON layer as an inorganic layer formed by sputtering and preferably contains 0.2 to 40% by weight of Al based on the total weight of the inorganic layer.

JP 2010-153085 A discloses that in order to ensure gas barrier properties and transparency, an SiAlON film is provided, which is formed by microwave plasma CVD and contains 10 atm % or less of an Al—O bond, which is calculated in terms of the amount of Al.

### SUMMARY OF INVENTION

On the other hand, in recent years, flexible electronic devices have also been required to have high durability as well as high performance. For example, gas barrier films have been required to exhibit high gas barrier properties even under harsher conditions. To meet the requirements, therefore, flexible electronic devices have become subjected to acceleration tests for high durability under harsher, high-temperature, high-humidity conditions such as 85° C. and 85% RH (relative humidity), although so far, flexible electronic devices have been subjected to acceleration tests for durability in an environment at about 60° C. and 90% RH (relative humidity).

Therefore, substrates for these flexible electronic devices and gas barrier films for use in the sealing thereof are also required to have higher durability so that they can exhibit gas barrier properties under harsh, high-temperature, high-humidity conditions.

However, JP 06-337406 A discloses only 70° C. and 95% RH as the harshest environment conditions for the evaluation of the gas barrier properties of the SiAlON film. JP 2009-220343 A discloses that the gas barrier properties of the gas barrier film are evaluated in an environment at 40° C. and 90% RH. JP 2010-153085 A discloses nothing about evaluation of the specific gas barrier properties of the SiAlON film. It has also been found that none of the gas barrier films disclosed in JP 06-337406 A, JP 2009-220343 A, and JP 2010-153085 A can have sufficient gas barrier properties after storage under harsher, high-temperature, high-humidity conditions such as 85° C. and 85% RH. In addition, none of JP 06-337406 A, JP 2009-220343 A, and JP 2010-153085 A disclose or suggest whether each element of the SiAlON film can have a suitable content range or whether the SiAlON film may contain other elements (such as carbon).

Thus, the present invention has been made in view of the above circumstances, and an object of the present invention is to provide a gas barrier film that has high gas barrier properties even after stored under harsh, high-temperature, high-humidity conditions such as 85° C. and 85% RH.

The inventor has conducted intensive studies to solve the above problems. As a result, the inventor has accomplished the present invention based on findings that a gas barrier film including a gas barrier layer with a specific composition makes it possible to solve the above problems.

Specifically, the object of the present invention is achieved by the following means.

A gas barrier film including: a substrate; and at least one gas barrier layer on the substrate, wherein

the gas barrier layer comprises at least one gas barrier layer A having a chemical composition of chemical formula (1),

[Chem. 1]

SiAl_{w}OₓN_{y}C_{z} (1)

wherein w, x, y, and z are elemental ratios of aluminum to silicon, oxygen to silicon, nitrogen to silicon, and carbon to silicon, respectively, measured in a thickness direction of the gas barrier layer, y is a maximum value of the elemental ratio of nitrogen to silicon measured in the thickness direction of the gas barrier layer and satisfies mathematical formula (1), and w, x, and z satisfy mathematical formulae (2) to (4)

[Math. 1]

0.05≦y≦0.20 mathematical formula (1)

0.07≦w≦0.20 mathematical formula (2)

1.90≦x≦2.40 mathematical formula (3)

0.00≦z≦0.20 mathematical formula (4)

respectively, when measured at a point where the elemental ratio of nitrogen to silicon is the maximum value.

### BRIEF DESCRIPTION OF DRAWINGS

FIG. 1 is a schematic diagram showing an example of a manufacturing apparatus suitable for use in manufacturing a gas barrier layer B according to the present invention. In FIG. 1, reference numeral S represents a deposition space, reference numeral 1 represents a substrate, reference numerals 1′ and 1″ each represent a substrate having undergone film deposition, reference numeral 10 represents an unwinding roll, reference numerals 11, 12, 13, and 14 each represent a feed roll, reference numeral 15 represents a first deposition roll, reference numeral 16 represents a second deposition roll, reference numeral 17 represents a winding roll, reference numeral 18 represents a gas supply pipe, reference numeral 19 represents a plasma generating power source, reference numerals 20 and 21 each represent a magnetic field generator, reference numeral 30 represents a vacuum chamber, reference numeral 40 represents a vacuum pump, and reference numeral 41 represents a controller.

### DESCRIPTION OF EMBODIMENTS

Hereinafter, modes for carrying out the present invention will be described in detail.

According to a first mode of the present invention, there is provided a gas barrier film including a substrate and at least one gas barrier layer on the substrate, wherein the gas barrier layer includes at least one gas barrier layer A having a chemical composition of chemical formula (1):

[Chem. 2]

SiAl_{w}OₓN_{y}C_{z} (1)

In the formula, w, x, y, and z are the elemental ratios of aluminum to silicon, oxygen to silicon, nitrogen to silicon, and carbon to silicon, respectively, measured in the thickness direction of the gas barrier layer, y is the maximum value of the elemental ratio of nitrogen to silicon measured in the thickness direction of the gas barrier layer and satisfies mathematical formula (1) below, and w, x, and z satisfy mathematical formulae (2) to (4) below,

[Math. 2]

0.05≦y≦0.20 Mathematical formula (1)

0.07≦w≦0.20 Mathematical formula (2)

1.90≦x≦2.40 Mathematical formula (3)

0.00≦z≦0.20 Mathematical formula (4)

respectively, when measured at the point where the elemental ratio of nitrogen to silicon is the maximum value (namely, the y value).

The gas barrier film of the present invention includes a substrate and a gas barrier layer A on the substrate, wherein the gas barrier layer A has the chemical composition of chemical formula (1) (SiAl_{w}OₓN_{y}C_{z}) in which the elemental ratios (atomic ratios) of aluminum to silicon, oxygen to silicon, nitrogen to silicon, and carbon to silicon satisfy the relations of mathematical formulae (1) to (4), respectively. The gas barrier film of the present invention with these features has high gas barrier properties and can exhibit high gas barrier properties even after stored under harsh, high-temperature, high-humidity conditions, such as 85° C. and 85% RH. According to the present invention, there is provided a gas barrier film that has high gas barrier properties and still has high gas barrier properties even after stored under harsh, high-temperature, high-humidity conditions.

Hereinafter, preferred embodiments of the present invention will be described. It should be noted that the embodiments below are not intended to limit the present invention. It should also be noted that dimensions and proportions in the drawing may be exaggerated for convenience of illustration and different from actual ones.

In the description, “X to Y” indicating a range means “equal to or more than X and equal to or less than Y.” In the description, “weight” and “mass,” “% by weight” and “% by mass,” or “parts by weight” and “parts by mass” are used as interchangeable terms. Unless otherwise specified, operations and measurement of physical properties and the like are performed under the conditions of room temperature (20 to 25° C.) and a relative humidity of 40 to 50%.

[Gas Barrier Film]

The gas barrier film of the present invention includes a substrate and a gas barrier layer. The gas barrier film of the present invention may further include an additional component, for example, between the substrate and the gas barrier layer, on the gas barrier layer, or on the surface of the substrate opposite to its surface on which the gas barrier layer is formed. In the present invention, the additional component may be of any type. Any component used for conventional gas barrier films may be used as it is or after appropriate modification. Specifically, the additional component may be an intermediate layer, a protective layer, a smooth layer, an anchor coat layer, a bleed-out preventing layer, a desiccant layer with water adsorbing properties, an antistatic layer, or any other functional layer.

In the present invention, the gas barrier layer may be a single layer or may have a multilayer structure of two or more layers.

When the gas barrier layer according to the present invention has a multilayer structure of two or more layers, these layers may be gas barrier layers with the same composition or different compositions. When the gas barrier layer according to the present invention has a multilayer structure of two or more layers, these layers may be gas barrier layers formed by the same method or different methods.

In the present invention, the gas barrier layer only has to be formed on at least one surface of the substrate. Therefore, the gas barrier film of the present invention encompasses both of a mode in which a gas barrier layer is formed on one surface of the substrate and another mode in which gas barrier layers are formed on both surfaces of the substrate.

<<Substrate>>

In the gas barrier film according to the present invention, a plastic film or sheet is generally used as the substrate. Preferably, a colorless transparent resin film or sheet is used as the substrate. The material, thickness, and other properties of the plastic film to be used are not limited and may be appropriately selected depending on the intended use, as long as the gas barrier layer and other components can be kept on the film. Specifically, the plastic film may be made of polyester resin, methacrylic resin, methacrylic acid-maleic acid copolymer, polystyrene resin, transparent fluororesin, polyimide, fluorinated polyimide resin, polyamide resin, polyamide imide resin, polyether imide resin, cellulose acylate resin, polyurethane resin, polyether ether ketone resin, polycarbonate resin, alicyclic polyolefin resin, polyarylate resin, polyethersulfone resin, polysulfone resin, cycloolefin copolymer, fluorene ring-modified polycarbonate resin, alicyclic-modified polycarbonate resin, fluorene ring-modified polyester resin, acryloyl compound, or other thermoplastic resin.

In the present invention, the substrate disclosed in paragraphs [0056] to [0075] of JP 2012-116101 A or the substrate disclosed in paragraphs [0125] to [0131] of JP 2013-226758 A may also be used as appropriate.

The substrate used in the gas barrier film according to the present invention typically has a thickness of 1 to 800 μm, preferably 10 to 200 μm, although it may have any thickness appropriately selected depending on the intended use. Any of these plastic films may also have a functional layer such as a transparent conductive layer, a primer layer, or a hard coat layer. Besides these layers, the layer described in paragraphs [0036] to [0038] of JP 2006-289627 A is preferably used as the functional layer.

The substrate preferably has high surface smoothness. Concerning the surface smoothness, the substrate preferably has an average surface roughness (Ra) of 2 nm or less. The lower limit of the surface roughness is practically, but not limited to, 0.01 nm or more. If necessary, both surfaces of the substrate or at least one surface on which the gas barrier layer is to be formed may be subjected to polishing for improving the smoothness.

<<Gas Barrier Layer>>

<Gas Barrier Layer A>

The gas barrier layer according to the present invention includes at least one gas barrier layer A.

Hereinafter, the gas barrier layer A according to the present invention will be described.

[Composition of Gas Barrier Layer A]

The gas barrier layer A according to the present invention has the chemical composition of chemical formula (1) below.

[Chem. 3]

SiAl_{w}OₓN_{y}C_{z} (1)

In the formula, w, x, y, and z are the elemental ratios (atomic ratios) of aluminum to silicon, oxygen to silicon, nitrogen to silicon, and carbon to silicon, respectively, measured in the thickness direction of the gas barrier layer, y is the maximum value of the elemental ratio of nitrogen to silicon measured in the thickness direction of the gas barrier layer and satisfies mathematical formula (1) below, and w, x, and z satisfy mathematical formulae (2) to (4) below, respectively, when measured at the point where the elemental ratio of nitrogen to silicon is the maximum value.

[Math. 3]

0.05≦y≦0.20 Mathematical formula (1)

0.07≦w≦0.20 Mathematical formula (2)

1.90≦x≦2.40 Mathematical formula (3)

0.00≦z≦0.20 Mathematical formula (4)

In general, irradiation with active energy rays such as excimer light is used to convert a polysilazane compound as a raw material for the gas barrier layer to silicon oxide, silicon nitride, or silicon oxynitride (in the description, such a conversion reaction is also referred to as “modification”). In such a modification process, the gas barrier layer can contain SiOₓC_{z}, SiOₓN_{y}C_{z}, or other compositions.

In a normal moist environment, the N site of the SiAl_{w}OₓN_{y}C_{z} composition can react with water vapor. This suggests that the gas barrier layer with a higher elemental ratio of nitrogen to silicon may have a higher ability to absorb (adsorb) water vapor and have more reliable gas barrier properties. However, if the elemental ratio of nitrogen to silicon is too high, storage under harsh, high-temperature, high-humidity conditions will allow Si—N—Si bonds to undergo hydrolysis due to moisture and heat, so that Si—OH will form, which will be partially involved in the formation of Si—O—Si bonds but consequently lead to the degradation of the gas barrier properties. In other words, if the elemental ratio of nitrogen to silicon is too high, the gas barrier properties will be rather degraded after storage under harsh, high-temperature, high-humidity conditions.

On the other hand, for example, when the modification is performed using excimer light, Si—N—Si bonds seem to play a role in efficiently absorbing the excimer light (172 nm) and promoting the modification. Therefore, it the elemental ratio of nitrogen to silicon is too low, the efficiency of the modification will decrease so that the resulting gas barrier film will have reduced gas barrier properties.

As mentioned above, the gas barrier properties after the storage under high-temperature, high-humidity conditions decreases with increasing elemental ratio of nitrogen to silicon, and the initial gas barrier properties decreases with decreasing elemental ratio of nitrogen to silicon. For the present invention, it has been found that in order to achieve both high initial gas barrier properties and high gas barrier properties after storage under high-temperature, high-humidity conditions, the maximum value y of the elemental ratio of nitrogen to silicon in the SiAl_{w}OₓN_{y}C_{z} composition must be in the range of mathematical formula (1) and should preferably satisfy mathematical formula (5) below.

[Math. 4]

0.05≦y≦0.20 Mathematical formula (1)

0.05≦y≦0.15 Mathematical formula (5)

As mentioned above, as the elemental ratio of nitrogen to silicon increases, the resistance to heat and moisture tends to decrease. In the present invention, therefore, the Al_{w}OₓN_{y}C_{z} composition measured at the point where the elemental ratio of nitrogen to silicon is the maximum is determined as an index of the resistance to heat and moisture, taking into account the distribution of the composition in the thickness direction of the gas barrier layer A. The composition of the gas barrier layer A according to the present invention with a distribution in the thickness direction preferably falls within the range specified according to the present invention over a part with a thickness of 50% or more of the entire thickness, more preferably over a part with a thickness of 80% or more of the entire thickness, even more preferably over the whole of the layer (namely, 100% of the entire thickness).

The aluminum component is added to the SiOₓN_{y}C_{z} composition to form the SiAl_{w}OₓN_{y}C_{z} composition, so that the modification can be uniformly performed, which is effective in improving the stability of Si—N—Si bonds under high-temperature, high-humidity conditions. If the Al content is low, the resulting stability of Si—N—Si bonds may be insufficient under high-temperature, high-humidity conditions. On the other hand, if the Al content is too high, the initial gas barrier properties may be affected adversely. For the present invention, therefore, it has been found that the elemental ratio w of aluminum to silicon measured at the point where the elemental ratio of nitrogen to silicon is the maximum must be in the range of mathematical formula (2) and should preferably satisfy mathematical formula (6) below.

[Math. 5]

0.07≦w≦0.20 Mathematical formula (2)

0.10≦w≦0.15 Mathematical formula (6)

The carbon component of the SiAl_{w}OₓN_{y}C_{z} composition is effective in improving the bending resistance of the film. For the present invention, therefore, it has been found that the elemental ratio z of carbon to silicon measured at the point where the elemental ratio of nitrogen to silicon is the maximum must be in the range of mathematical formula (4) and should preferably satisfy mathematical formula (8) below. When the z value is in these ranges, the bending resistance can be improved without degrading the initial gas barrier properties or the gas barrier properties after storage under high-temperature, high-humidity conditions.

[Math. 6]

0.00≦z≦0.20 Mathematical formula (4)

0.00≦z≦0.10 Mathematical formula (8)

For the present invention, it has also been found that in order to achieve both high gas barrier properties and high compositional stability under harsh, high-temperature, high-humidity conditions, the elemental ratio x of oxygen to silicon in the SiAl_{w}OₓN_{y}C_{z} composition must be in the range of mathematical formula (3) and should preferably satisfy mathematical formula (7) below, when measured at the point where the elemental ratio of nitrogen to silicon is the maximum.

[Math. 7]

1.90≦x≦2.40 Mathematical formula (3)

2.00≦x≦2.25 Mathematical formula (7)

Therefore, in order to form a gas barrier film having high gas barrier properties and still having high gas barrier properties even after storage under harsh, high-temperature, high-humidity conditions, the gas barrier layer A according to the present invention must be such that w, x, y, and z satisfy mathematical formulae (1) to (4) at the same time, in which w, x, y, and z are the elemental ratios of aluminum to silicon, oxygen to silicon, nitrogen to silicon, and carbon to silicon, respectively, in the SiAl_{w}OₓN_{y}C_{z} composition. In addition, at least one of w, x, y, and z preferably satisfies one of mathematical formulae (5) to (8) above, and more preferably, w, x, y, and z satisfy mathematical formulae (5) to (8) at the same time.

In the present invention, the w, x, y, and z values can be determined, for example, by measuring the elemental ratio (atomic ratio) of each constituent element in the thickness direction using the instrument and method (XPS analysis method) described below. As used herein, the term “thickness direction” refers to the direction of the thickness of a thin film layer (e.g., a gas barrier layer), which runs straight to the direction parallel to its surface.

More specifically, the elemental ratio of nitrogen to silicon is measured in the thickness direction over the entire thickness of the gas barrier layer A. When the resulting maximum value y of the ratio of nitrogen to silicon is in the range of mathematical formula (1), the w, x, and z values are determined at the point where the maximum y value is obtained in the measurement. It should be noted that when the gas barrier layer A is the uppermost layer, data at the first initial measurement point should be excluded.

When the gas barrier layer A is adjacent to another layer, it is determined from the continuity of data whether or not the composition of the adjacent layer has an influence on the measurement at a point on the boundary with the adjacent layer. If it is determined that the composition of the adjacent layer has an influence, such a measurement point will be excluded. For example, if a hard coat layer is provided adjacent to the gas barrier layer A according to the present invention, it will be apparent to those skilled in the art that the elemental ratio z of carbon to silicon in the hard coat layer is 100 or more. This makes it possible to determine, from the measured z value, whether or not the composition of the adjacent layer has an influence. Therefore, in the present invention, the measurement point at which the z value is 1 or more should be excluded based on the decision that the adjacent layer concerned has an influence on the measurement. When the layer adjacent to the gas barrier layer A according to the present invention has a composition similar to that of the gas barrier layer A, measurement points may be excluded as follows.

Separately, the adjacent layer with a composition similar to that of the gas barrier layer A is formed alone under the same conditions, and then its composition is measured in the thickness direction by the same method. The resulting composition profile in the thickness direction is compared with the composition profile of the layer actually adjacent to the gas barrier layer A. As a result of the comparison, measurement points are excluded when determined as corresponding to the boundary between the adjacent layer and the gas barrier layer A.

In the present invention, the Al_{w}OₓN_{y}C_{z} composition is measured in the thickness direction of the gas barrier layer A by the XPS analysis method described below. In this regard, the gas barrier layer A is deemed to have substantially the same composition in each in-plane direction perpendicular to the thickness direction.

The y value in the Al_{w}OₓN_{y}C_{z} composition of the gas barrier layer A is the maximum value of the elemental ratio of nitrogen to silicon, which is obtained by performing the measurement a statistically significant number of times (e.g., three times over the entire thickness) by the XPS analysis method described below.

XPS Analysis Conditions

Instrument: QuanteraSXM (manufactured by ULVAC-PHI, Inc.)

X-ray source: monochromatic Al-Kα

Measurement region: Si2p, C1s, N1s, O1s, Al

Sputtering ion: Ar (2 keV)

Depth profile: The measurement is repeated after 1 minute sputtering.

A single measurement corresponds to an about 5-nm-thick part of a SiO₂ thin film standard sample.

Quantification: The background is determined by the Shirley method, and the quantification from the resulting peak area is performed using a relative sensibility coefficient method.

Data Processing: MultiPak (Manufactured by ULVAC-PHI, Inc.)

When the gas barrier layer A according to the present invention is the uppermost layer, the data obtained by the first measurement should be excluded because the data is affected by water adsorbed on the surface or by contamination with organic materials. When the gas barrier layer A according to the present invention is adjacent to another layer, it is determined from the continuity of data whether or not the composition of the adjacent layer has an influence on the measurement at a point on the boundary between the gas barrier layer A and the adjacent layer. If it is determined that the composition of the adjacent layer has an influence, such a measurement point will be excluded.

The gas barrier layer A according to the present invention may be a single layer or a multilayer structure of two or more sublayers. When the gas barrier layer A is a multilayer structure of two or more sublayers, the sublayers may have the same or different compositions as long as each sublayer has the chemical composition of chemical formula (1).

The gas barrier layer A according to the present invention may have any thickness as long as the effects of the present invention are not impaired. The thickness of the gas barrier layer A is preferably 1 to 500 nm, more preferably 5 to 300 nm, even more preferably 10 to 200 nm.

[Methods for Forming the Gas Barrier Layer A]

Next, preferred methods for forming the gas barrier layer A according to the present invention will be described. The gas barrier film of the present invention can be produced by forming the gas barrier layer A according to the present invention on at least one surface of the substrate. A non-liming method for forming the gas barrier layer A according to the present invention on the surface of the substrate may include, for example, applying a coating liquid containing a compound or compounds including silicon, aluminum, oxygen, nitrogen, and carbon, preferably a coating liquid containing a nitrogen-containing silicon compound and an aluminum compound, more preferably a coating liquid containing a polysilazane compound and an organic aluminum compound; drying the coating liquid to form a coating film A; and applying energy (for modification) to the coating film A. The phrase “forming the gas barrier layer A according to the present invention on at least one surface of the substrate” or “forming the gas barrier layer A according to the present invention on the surface of the substrate” may mean not only that the gas barrier layer A is formed directly on the surface of the substrate, but also that the gas barrier layer A is formed on the surface of the substrate with any other layer interposed therebetween.

(Nitrogen-Containing Silicon Compound)

An organic aluminum compound and a nitrogen-containing silicon compound may be used together in the preparation of a coating liquid for forming the gas barrier layer A according to the present invention. The nitrogen-containing silicon compound may be of any type as long as it can form a coating liquid. Examples of the nitrogen-containing silicon compound that may be used include a polysilazane compound, a silazane compound, an aminosilane compound, a silylacetamide compound, a silylimidazole compound, and other nitrogen-containing silicon compounds.

(Polysilazane Compound)

In the present invention, the polysilazane compound is a silicon-nitrogen bond-containing polymer. Specifically, the polysilazane compound is an inorganic polymer having Si—N, Si—H, and N—H bonds and serving as a precursor for ceramics such as SiO₂, Si₃N₄, and SiOₓN_{y} as an intermediate solid solution between them. In the description, “polysilazane compound” is sometimes abbreviated as “polysilazane.”

Examples of the polysilazane for use in the present invention include, but are not limited to, those known in the art. For example, those disclosed in paragraphs [0043] to [0058] of JP 2013-022799 A or those disclosed in paragraphs [0038] to [0056] of JP 2013-226758 A may be used as appropriate. Among them, perhydropolysilazane is most preferably used.

The polysilazane compound is also commercially available in the form of a solution in an organic solvent. Commercially available products of such a polysilazane solution include NN120-10, NN120-20, NAX120-20, NN110, NN310, NN320, NL110A, NL120A, NL120-20, NL150A, NP110, NP140, and SP140 manufactured by AZ Electronic Materials.

Other examples of the polysilazane compound that may be used in the present invention include, but are not limited to, silicon alkoxide-added polysilazane (JP 05-238827 A) obtained by reaction of polysilazane with silicon alkoxide, glycidol-added polysilazane (JP 06-122852 A) obtained by reaction with glycidol, alcohol-added polysilazane (JP 06-240208 A) obtained by reaction with alcohol, metal carboxylate-added polysilazane (JP 06-299118 A) obtained by reaction with metal carboxylate, acetylacetonate complex-added polysilazane (JP 06-306329 A) obtained by reaction with a metal-containing acetylacetonate complex, metal fine particle-added polysilazane (JP 07-196986 A) obtained by adding metal fine particles, and other polysilazane compounds capable of being converted to ceramic materials at low temperature.

(Silazane Compound)

Examples of the silazane compound for preferred use in the present invention include, but are not limited to, dimethyldisilazane, trimethyldisilazane, tetramethyldisilazane, pentamethyldisilazane, hexamethyldisilazane, and 1,3-divinyl-1,1,3,3-tetramethyldisilazane.

(Aminosilane Compound)

Examples of the aminosilane compound for preferred used in the present invention include, but are not limited to, 3-aminopropyltrimethoxysilane, 3-aminopropyldimethylethoxysilane, 3-arylaminopropyltrimethoxysilane, propylethylenediaminesilane, N-[3-(trimethoxysilyl)propyl]ethylenediamine, 3-butylaminopropyltrimethylsilane, 3-dimethylaminopropyldiethoxymethylsilane, 2-(2-aminoethylthioethyl)triethoxysilane, and bis(butylamino)dimethylsilane.

(Silylacetamide Compound)

Examples of the silylacetamide compound for preferred use in the present invention include, but are not limited to, N-methyl-N-trimethylsilylacetamide, N,O-bis(tert-butyldimethylsilyl)acetamide, N,O-bis(diethylhydrogensilyl)trifluoroacetamide, N,O-bis(trimethylsilyl)acetamide, and N-trimethylsilylacetamide.

(Silylimidazole Compound)

Examples of the silylimidazole compound for preferred use in the present invention include, but are not limited to, 1-(tert-butyldimethylsilyl)imidazole, 1-(dimethylethylsilyl)imidazole, 1-(dimethylisopropylsilyl)imidazole, and N-trimethylsilylimidazole.

(Other Nitrogen-Containing Silicon Compounds)

In the present invention, other nitrogen-containing silicon compounds than the above may be used, examples of which include, but are not limited to, bis(trimethylsilyl)carbodiimide, trimethylsilylazide, N,O-bis(trimethylsilyl)hydroxylamine, N,N′-bis(trimethylsilyl)urea, 3-bromo-1-(triisopropylsilyl)indole, 3-bromo-1-(triisopropylsilyl)pyrrole, N-methyl-N,O-bis(trimethylsilyl)hydroxylamine, 3-isocyanatopropyltriethoxysilane, and silicon tetraisothiocyanate.

Among the above nitrogen-containing silicon compounds, polysilazane compounds such as perhydropolysilazane and organopolysilazane are preferred in view of film formability with less defects such as cracks and less residues of organic materials, and perhydropolysilazane is particularly preferred because it can provide high gas barrier performance and can form a film that exhibits gas barrier performance even when bent and even under high-temperature, high-humidity conditions.

(Aluminum Compound)

The aluminum compound for use in the present invention may be of any type. An organic aluminum compound such as an aluminum alkoxide or an aluminum chelate compound is preferably used as the aluminum compound. In the present invention, the term “aluminum alkoxide” refers to a compound having at least one alkoxy group bonded to aluminum.

Examples of the organic aluminum compound for use in the present invention include, but are not limited to, aluminum trimethoxide, aluminum triethoxide, aluminum tri-n-propoxide, aluminum triisopropoxide, aluminum tri-n-butoxide, aluminum tri-sec-butoxide, aluminum tri-tert-butoxide, aluminum acetylacetonate, acetoalkoxyaluminum diisopropylate, aluminum ethylacetoacetate diisopropylate, aluminum ethylacetoacetate di-n-butyrate, aluminum diethylacetoacetate mono-n-butyrate, aluminum diisopropylate mono-sec-butyrate, aluminum trisacetylacetonate, aluminum trisethylacetoacetate, bis(ethylacetoacetate) (2, 4-pentanedionato)aluminum, aluminum alkylacetoacetate diisopropylate, aluminum oxide isopropoxide trimer, and aluminum oxide octylate trimer.

In the present invention, the aluminum compound to be used may be a commercially available product or a synthetic product. Examples of such a commercially available product include AMD (aluminum diisopropylate mono-sec-butyrate), ASBD (aluminum sec-butyrate), ALCH (aluminum ethylacetoacetate diisopropylate), ALCH-TR (aluminum trisethylacetoacetate), Alumichelate M (aluminum alkylacetoacetate diisopropylate), Alumichelate D (aluminum bisethylacetoacetate monoacetylacetonate), and Alumichelate A (W) (aluminum trisacetylacetonate) (all manufactured by Kawaken Fine Chemicals Co., Ltd.), and PLENACT (registered trademark) AL-M (acetoalkoxyaluminum diisopropylate, manufactured by Ajinomoto Fine-Techno Co., Inc.)

The elemental ratio w of aluminum to silicon in the gas barrier layer A according to the present invention can be controlled by controlling the added amount of the aluminum compound relative to the amount of silicon element in the polysilazane. More specifically, for example, when commercially available perhydropolysilazane is used as the polysilazane compound, a sample may be prepared by applying the perhydropolysilazane onto a silicon wafer under a nitrogen atmosphere and then drying the applied material, and the composition of the resulting sample may be analyzed by XPS, so that the N/Si ratio of the perhydropolysilazane can be determined. Once the N/Si ratio is determined, a putative structure model can be made in which Si and N are bonded in that ratio, and the H ratio can be estimated from the model. Specifically, if commercially available perhydropolysilazane is determined to have a composition of SiN_{0.8}H₂ (in which the N/Si ratio is a result of analysis, and the H ratio is the value estimated from the putative structure model), it can be concluded to have a cyclic structure. If it has a straight-chain structure, it will have a composition of SiN₁H₃. Thus, the amount of the aluminum compound to be added can be determined in such a way that the w value in the SiAl_{w}OₓN_{y}C_{z} composition will fall within the range specified in the present invention.

The elemental ratio x of oxygen to silicon in the gas barrier layer A according to the present invention tends to increase as the added amount of the aluminum compound increases. On the other hand, the elemental ratio y of nitrogen to silicon tends to decrease as the added amount of the aluminum compound increases. Therefore, when the type (for reactivity) and added amount of the aluminum compound are controlled, the x and y values in the SiAl_{w}OₓN_{y}C_{z} composition can be controlled so as to fall within the ranges specified in the present invention, although they are not completely independent from each other.

The elemental ratio z of carbon to silicon in the gas barrier layer A according to the present invention can be controlled independently of w by selecting aluminum compounds with different ratios between aluminum and carbon or by increasing or reducing excimer radiation energy. Specifically, for example, z can be reduced by increasing the quantity of excimer radiation energy. In order for the z value to fall within the range specified in the present invention, it is preferable to use an aluminum compound with an alkyl chain of 6 or less carbon atoms, and it is more preferable to use an aluminum compound with an alkyl chain of 5 or less carbon atoms, among the aluminum compounds listed above. More specifically, examples that are preferably used include aluminum tri-n-butoxide, aluminum tri-sec-butoxide, aluminum tri-tert-butoxide, aluminum triisopropoxide, diisopropoxyaluminum ethylacetoacetate, aluminum di-sec-butoxide ethylacetoacetate, and aluminum sec-butoxide bis(ethylacetoacetate).

As long as the effects of the present invention are not impaired, the coating liquid for forming the gas barrier layer A according to the present invention may also contain a nitrogen-free silicon compound in addition to the nitrogen-containing silicon compound and the organoaluminum compound. Examples of such a nitrogen-free silicon compound include silsesquioxane, tetramethylsilane, trimethylmethoxysilane, dimethyldimethoxysilane, methyltrimethoxysilane, trimethylethoxysilane, dimethyldiethoxysilane, methyltriethoxysilane, tetramethoxysilane, tetramethoxysilane, hexamethyldisiloxane, hexamethyldisilazane, 1,1-dimethyl-1-silacyclobutane, trimethylvinylsilane, methoxydimethylvinylsilane, trimethoxyvinylsilane, ethyltrimethoxysilane, dimethyldivinylsilane, dimethylethoxyethynylsilane, diacetoxydimethylsilane, dimethoxymethyl-3,3,3-trifluoropropylsilane, 3,3,3-trifluoropropyltrimethoxysilane, aryltrimethoxysilane, ethoxydimethylvinylsilane, methyltrivinylsilane, diacetoxymethylvinylsilane, methyltriacetoxysilane, aryloxydimethylvinylsilane, diethylvinylsilane, butyltrimethoxysilane, tetravinylsilane, triacetoxyvinylsilane, tetraacetoxysilane, 3-trifluoroacetoxypropyltrimethoxysilane, diaryldimethoxysilane, butyldimethoxyvinylsilane, trimethyl-3-vinylthiopropylsilane, phenyltrimethylsilane, dimethoxymethylphenylsilane, phenyltrimethoxysilane, 3-acryloxypropyldimethoxymethylsilane, 3-acryloxypropyltrimethoxysilane, dimethylisopentyloxyvinylsilane, 2-aryloxyethylthiomethoxytrimethylsilane, 3-glycidoxypropyltrimethoxysilane, hexyltrimethoxysilane, heptadecafluorodecyltrimethoxysilane, dimethylethoxyphenylsilane, benzoyloxytrimethylsilane, 3-methacryloxypropyldimethoxymethylsilane, 3-methacryloxypropyltrimethoxysilane, dimethylethoxy-3-glycidoxypropylsilane, dibutoxydimethylsilane, divinylmethylphenylsilane, diacetoxymethylphenylsilane, dimethyl-p-tolylvinylsilane, p-styryltrimethoxysilane, diethylmethylphenylsilane, benzyldimethylethoxysilane, diethoxymethylphenylsilane, decylmethyldimethoxysilane, diethoxy-3-glycidoxypropylmethylsilane, octyloxytrimethylsilane, phenyltrivinylsilane, tetraaryloxysilane, dodecyltrimethylsilane, diarylmethylphenylsilane, diphenylmethylvinylsilane, diphenylethoxymethylsilane, diacetoxydiphenylsilane, dibenzyldimethylsilane, diaryldiphenylsilane, octadecyltrimethylsilane, methyloctadecyldimethylsilane, docosylmethyldimethylsilane, 1,3-divinyl-1,1,3,3-tetramethyldisiloxane, 1,4-bis(dimethylvinylsilyl)benzene, 1,3-bis(3-acetoxypropyl)tetramethyldisiloxane, 1,3,5-trimethyl-1,3,5-trivinylcyclotrisiloxane, 1,3,5-tris(3,3,3-trifluoropropyl)-1,3,5-trimethylcyclotrisiloxane, octamethylcyclotetrasiloxane, 1,3,5,7-tetraethoxy-1,3,5,7-tetramethylcyclotetrasiloxane, and decamethylcyclopentasiloxane. These silicon compounds may be used alone or in combination of two or more.

(Coating Liquid for Forming Gas Barrier Layer A)

The coating liquid for forming the gas barrier layer A according to the present invention can be prepared by dissolving, in an appropriate solvent, a compound or compounds including silicon, aluminum, oxygen, nitrogen, and carbon. Preferably, the coating liquid can be prepared by dissolving, in an appropriate solvent, the nitrogen-containing silicon compound and the organic aluminum compound. Alternatively, the coating liquid for forming the gas barrier layer A according to the present invention may be prepared by mixing the nitrogen-containing silicon compound and the organic aluminum compound and dissolving the mixture in an appropriate solvent. Alternatively, the coating liquid for forming the gas barrier layer A according to the present invention may be prepared by a process including dissolving the nitrogen-containing silicon compound in an appropriate solvent to forma coating liquid (1) containing the nitrogen-containing silicon compound, dissolving the organic aluminum compound in an appropriate solvent to form a coating liquid (2) containing the organic aluminum compound, and mixing the coating liquids (1) and (2). In view of the stability of the liquid, the coating liquid is more preferably prepared by using the same solvent to form the coating liquid (1) containing the nitrogen-containing silicon compound and to form the coating liquid (2) containing the organic aluminum compound and mixing the coating liquids (1) and (2). The coating liquid (1) may contain a single silicon compound containing nitrogen or contain two or more silicon compounds containing nitrogen. The coating liquid (1) may further contain the nitrogen-free silicon compound. Similarly, the coating liquid (2) may contain a single organic aluminum compound or two or more organic aluminum compounds.

In the present invention, the solvent for use in the preparation of the coating liquid for forming the gas barrier layer A may be of any type capable of dissolving the nitrogen-containing silicon compound and the aluminum compound. For example, when a polysilazane compound is used as the nitrogen-containing silicon compound, the solvent is preferably an organic solvent being inert to the polysilazane compound and being free of water and a reactive group (e.g., a hydroxyl group or an amine group) capable of easily reacting with the polysilazane compound, more preferably an aprotic organic solvent. Specifically, examples of the solvent include aprotic solvents such as hydrocarbon solvents including pentane, hexane, cyclohexane, toluene, xylene, Solvesso, turpentine, and other aliphatic, alicyclic, and aromatic hydrocarbons; halogen hydrocarbon solvents including methylene chloride and trichloroethane; esters including ethyl acetate and butyl acetate; ketones including acetone and methyl ethyl ketone; and ethers including dibutyl ether, dioxane, tetrahydrofuran, mono- and polyalkylene glycol dialkyl ethers (diglymes). These solvents may be used alone or in a mixture of two or more.

In the present invention, the concentration of the solid of the nitrogen-containing silicon compound in the coating liquid (1) is preferably 0.1 to 30% by mass, more preferably 0.5 to 20% by mass, even more preferably 1 to 15% by mass, based on the amount of the coating liquid (1), although it may be at any level and depend on the thickness of the layer or the pot life of the coating liquid.

In the present invention, the concentration of the solid of the aluminum compound in the coating liquid (2) is preferably 0.1 to 50% by mass, more preferably 0.5 to 20% by mass, even more preferably 1 to 10% by mass, based on the amount of the coating liquid (2), although it may be at any level and depend on the thickness of the layer or the pot life of the coating liquid.

In the present invention, when the coating liquids (1) and (2) are mixed, the mass mixing ratio (coating liquid (1): coating liquid (2)) is preferably, for example, 95:5 to 30:70, although it cannot be simply determined and should be appropriately determined taking into account the type of the compounds in the coating liquids.

In the present invention, the coating liquids (1) and (2) are preferably mixed under an inert gas atmosphere. Particularly when an aluminum alkoxide is used in the coating liquid (2), this should be performed to prevent the aluminum alkoxide from undergoing oxidation reaction with water and oxygen in the air.

In order to control the reactivity, the coating liquids (1) and (2) are preferably mixed with stirring and heating at 30 to 90° C.

The coating liquid for forming the gas barrier layer A according to the present invention preferably contains a catalyst for promoting modification. The catalyst that may be used in the present invention is preferably a basic catalyst. Specifically, examples of the catalyst include amine catalysts such as N,N-dimethylethanolamine, N,N-diethylethanolamine, triethanolamine, triethylamine, 3-morpholinopropylamine, N,N,N′,N′-tetramethyl-1,3-diaminopropane, and N,N,N′,N′-tetramethyl-1,6-diaminohexane; metal catalysts such as Pt compounds including Pt acetylacetonate, Pd compounds including Pd propionate, and Rh compounds including Rh acetylacetonate; and N-heterocyclic compounds. Among them, amine catalysts are preferably used. The concentration of the catalyst added in this case is preferably 0.1 to 10% by weight, more preferably 0.5 to 7% by weight, based on the weight of the silicon compound. When the catalyst content is in these ranges, excessive formation of silanol, a reduction in film density, and an increase in film defects can be avoided, which would otherwise be caused by abrupt progress of the reaction.

If necessary, the coating liquid for forming the gas barrier layer A according to the present invention may contain any of the additives listed below. Examples include cellulose ethers and cellulose esters, such as ethyl cellulose, nitrocellulose, cellulose acetate, and cellulose acetobutyrate; natural resins such as rubber and rosin resin; synthetic resins such as polymer resins; and condensation resins such as aminoplast, especially urea resins, melamine formaldehyde resins, alkyd resins, acrylic resins, polyesters or modified polyesters, epoxide, polyisocyanates or block polyisocyanates, and polysiloxanes.

(Method for Applying the Coating Liquid for Forming Gas Barrier Layer A)

The coating liquid for forming the gas barrier layer A according to the present invention may be applied using an appropriate conventionally known wet coating method. Examples include spin coating, roll coating, flow coating, inkjet method, spray coating, printing, dip coating, die coating, film casting, bar coating, and gravure coating.

The coating thickness may be appropriately selected depending on the purpose. For example, the coating thickness is preferably 1 to 500 nm, more preferably 5 to 300 nm, even more preferably 10 to 200 nm, as a dry thickness, per single gas barrier layer A. When the coating thickness is 1 nm or more, the coating can have sufficient barrier properties. When the coating thickness is 500 nm or less, stable coatability can be achieved during the formation of the layer, and the resulting coating can have high light transparency.

After the coating liquid is applied, the coating film A is preferably dried. The organic solvent can be removed from the coating film. A by drying the coating film A. In this process, the organic solvent may be entirely removed from the coating film A or may partially remain in the coating film A. Even when the organic solvent is allowed to remain partially, a good gas barrier layer A-forming coating liquid can be obtained. The remaining solvent can be removed later.

The coating film A is preferably dried at a temperature of 50 to 200° C. although it depends on the substrate used. For example, when the substrate used is a polyethylene terephthalate substrate with a glass transition temperature (Tg) of 70° C., the drying temperature is preferably set at 150° C. or lower taking into account heat-induced deformation of the substrate and the like. The temperature can be set using a hot plate, an oven, a furnace, or the like. The drying time is preferably set relatively short. For example, when the drying temperature is 150° C., the drying time is preferably set at 30 minutes or less. The drying may be performed under any of an air atmosphere, a nitrogen atmosphere, an argon atmosphere, a vacuum atmosphere, and a reduced-pressure atmosphere with a controlled oxygen concentration.

The coating film A obtained by the application of the coating liquid for forming the gas barrier layer A according to the present invention may be subjected to the step of removing water before or during the modification treatment. The method of removing water preferably includes maintaining a low-humidity environment for dehumidification. Since the humidity of the low-humidity environment depends on the temperature, a preferred mode of the relationship between the temperature and the humidity can be defined using the dew-point temperature. The dew-point temperature is preferably 4° C. or lower (temperature 25° C./humidity 25%), more preferably −5° C. or lower (temperature 25° C./humidity 10%). It is preferable to appropriately set the holding time depending on the thickness of the gas barrier layer A. Under conditions where the gas barrier layer A has a thickness of 1.0 μm or less, the dew-point temperature is preferably −5° C. or lower, and the holding time is preferably 1 minute or more. The lower limit of the dew-point temperature is generally, but not limited to, −50° C. or higher, preferably −40° C. or higher. The removal of water before or during the modification treatment is a preferred mode for the facilitation of the dehydration reaction of the gas barrier layer A having undergone conversion to silanol.

(Application of Energy to Gas Barrier Layer A)

In the present invention, the application of energy to the gas barrier layer A (modification treatment) may refer to a reaction in which energy is applied to the coating film. A so that the nitrogen-containing silicon compound and the aluminum compound are converted to the chemical composition of chemical formula (1), and may also refer to a treatment for forming an inorganic thin film with a quality level that contributes to allowing the whole of the gas barrier film of the present invention to have gas barrier properties.

Such application of energy (modification treatment) may be performed by a known method such as a plasma treatment or an active energy ray irradiation treatment. In particular, an active energy ray irradiation treatment is preferred because it allows low-temperature modification and has a high degree of freedom for the selection of the substrate type.

(Plasma Treatment)

In the present invention, a plasma treatment may be used as the modification treatment. The plasma treatment may be performed using a known method. Preferred examples include an atmospheric pressure plasma treatment and the like. Atmospheric pressure plasma CVD, in which a plasma CVD treatment is performed near the atmospheric pressure, needs not to use reduced pressure in contrast to vacuum plasma CVD and has not only high productivity but also high deposition rate because of its high plasma density. Atmospheric pressure plasma CVD can also form extremely uniform films because its mean free path of gas is very short under the atmospheric pressure, which is a high pressure condition as compared with that of general CVD.

In the atmospheric pressure plasma treatment, the discharge gas may be nitrogen gas or gas of group 18 of the long form of the periodic table, such as helium, neon, argon, krypton, xenon, or radon. Among them, nitrogen, helium, or argon is preferably used, and nitrogen is inexpensive and particularly preferred.

(Active Energy Ray Irradiation Treatment)

The active energy ray may be, for example, an infrared ray, a visible ray, an ultraviolet ray, an X ray, an electron beam, an α ray, a β ray, a γ ray, or the like. An electron beam or an ultraviolet ray is preferred, and an ultraviolet ray is more preferred. When an ultraviolet ray (with the same meaning as “ultraviolet light”) is used, ozone or active oxygen atoms can be produced, which have high oxidizing ability and allows low-temperature formation of silicon-containing films with high denseness and insulating properties.

The ultraviolet irradiation treatment may be performed using any ultraviolet ray generator conventionally employed.

As used herein, the term “ultraviolet ray” generally refers to an electromagnetic wave with a wavelength of 10 to 400 nm. Ultraviolet rays with a wavelength of 210 to 375 nm are preferably used in the case of the ultraviolet irradiation treatment other than the vacuum ultraviolet (10 to 200 nm) treatment described below.

For the ultraviolet irradiation, the irradiation intensity and the irradiation time are preferably selected so as not to damage the substrate on which the silicon-containing film being irradiated is supported.

In general, when the substrate is a plastic film or the like, the substrate can suffer from degradation of its properties, such as deformation or strength reduction, at a temperature of 150° C. or higher during the ultraviolet irradiation treatment. However, when the substrate is a highly heat-resistant film such as a polyimide film or a metal substrate, the modification treatment can be performed at higher temperatures. Therefore, the substrate temperature during the ultraviolet irradiation generally has no upper limit and may be appropriately selected, depending on the substrate type, by those skilled in the art. The atmosphere for the ultraviolet irradiation treatment may also be of any type.

Examples of means for generating such ultraviolet rays include, but are not limited to, metal halide lamps, high-pressure mercury lamps, low-pressure mercury lamps, xenon arc lamps, carbon arc lamps, excimer lamps (with a single wavelength of 172 nm, 222 nm, or 308 nm, e.g., manufactured by USHIO INC. or M.D.COM, Inc.), and UV light lasers. Preferably, the ultraviolet rays from the generator are reflected by a reflector and then applied to the silicon-containing film in order to improve efficiency and achieve uniform irradiation.

The ultraviolet irradiation can be adapted to both a batch process and a continuous process, which may be appropriately selected depending on the shape of the substrate used. For example, in a batch process, the laminate having the silicon-containing film at the surface may be treated in an ultraviolet baking furnace with an ultraviolet light generator as mentioned above. The ultraviolet baking furnace is generally known per se. For example, an ultraviolet backing furnace manufactured by EYE GRAPHICS CO., LTD. may be used. When the laminate having the silicon-containing film at the surface is a long film, ultraviolet rays may be continuously applied to the film in a drying zone having an ultraviolet light generator as mentioned above so that the conversion to a ceramic can be continuously performed. The time required for the ultraviolet irradiation is generally 0.1 seconds to 10 minutes, preferably 0.5 seconds to 3 minutes, although it depends on the type of the substrate used, the composition of the silicon-containing film, and the concentration.

(Vacuum Ultraviolet Irradiation Treatment (Excimer Irradiation Treatment))

In the present invention, the modification treatment is most preferably a vacuum ultraviolet irradiation treatment (excimer irradiation treatment). The vacuum ultraviolet irradiation treatment may be a process of directly cleaving bonds between atoms in the polysilazane compound by the action of photons alone, called a photon process, using light energy at a wavelength of 100 to 200 nm, preferably 100 to 180 nm, larger than the interatomic bonding strength of the polysilazane compound, while allowing an oxidation reaction with active oxygen or ozone to proceed, so that a silicon oxide film can be formed at relatively low temperatures (about 200° C. or lower).

In the present invention, the radiation source may of any type capable of emitting light with a wavelength of 100 to 180 nm. Preferred examples include an excimer radiator (e.g., Xe excimer lamp) with maximum radiation at about 172 nm, a low-pressure mercury vapor lamp with a bright line at about 185 nm, medium- and high-pressure mercury vapor lamps with a wavelength component at 230 nm or less, and an excimer lamp with maximum radiation at about 222 nm.

Among them, the Xe excimer lamp emits ultraviolet light with a single wavelength as short as 172 nm and thus has high luminous efficiency. At the wavelength of this light, oxygen has a high absorption coefficient, which makes it possible to produce radical oxygen species or ozone at a high concentration from a small amount of oxygen.

Light energy at a short wavelength of 172 nm is known to have high ability to dissociate bonds in organic materials. The polysilazane layer can be modified in a short time using the active oxygen or ozone and the high energy of the ultraviolet radiation.

The excimer lamp, which has a high luminous efficiency, can be turned on with a low-power input. The excimer lamp is also characterized in that it does not emit light with a long wavelength that can cause a rise in temperature, and emits energy in the ultraviolet region, in other words, at a short wavelength, so that the rise in the surface temperature of the irradiated object can be suppressed. Therefore, the excimer lamp is suitable for a flexible film material such as PET, which is considered to be vulnerable to heat.

Oxygen is necessary for the reaction during the ultraviolet irradiation. However, vacuum ultraviolet light is absorbed by oxygen, which will tend to reduce the efficiency of the ultraviolet irradiation process. Therefore, the vacuum ultraviolet irradiation is preferably performed at oxygen and water-vapor concentrations as low as possible. Although it may depend on the added amount of the aluminum compound, as the oxygen concentration during the excimer irradiation is reduced to an extremely low level such as 50 ppm by volume or less, the elemental ratio x of oxygen to silicon in the SiAl_{w}OₓN_{y}C_{z} composition of the layer A according to the present invention tends to decrease, whereas the elemental ratios y and z of nitrogen to silicon and carbon to silicon tend to increase. However, even if the oxygen concentration is increased to more than 10,000 ppm by volume during the excimer irradiation, the x value will not increase, and excimer light will be rather absorbed by oxygen in the atmosphere, which may reduce the irradiation efficiency. In the present invention, therefore, the oxygen concentration during the vacuum ultraviolet irradiation is preferably controlled in the range of 10 to 10,000 ppm by volume, more preferably in the range of 20 to 5,000 ppm by volume, as appropriate. The water-vapor concentration during the conversion process is preferably, but not limited to, 1,000 to 4,000 ppm by volume.

During the vacuum ultraviolet irradiation, the irradiation atmosphere is preferably filled with dry inert gas, more preferably dry nitrogen gas particularly in view of cost. The oxygen concentration can be controlled by measuring the flow rates of oxygen gas and inert gas being introduced into the irradiation chamber and then changing the ratio between the flow rates.

Although it may depend on the type of the aluminum compound, the elemental ratio z of carbon to silicon in the SiAl_{w}OₓN_{y}C_{z} composition of the layer A according to the present invention tends to decrease as the quantity of the energy of vacuum ultraviolet light applied to the coating film A surface increases, and therefore can be reduced to 0 (in other words, a carbon-free state). In the present invention, therefore, the quantity of the energy of ultraviolet light applied to the coating film A surface is preferably controlled in the range of 1 to 10 J/cm². If it is less than 1 J/cm², the modification may be insufficient. If it is more than 10 J/cm², the modification may be excessive so that cracking or thermal deformation of the substrate may occur.

The vacuum ultraviolet light for use in the modification may be generated using a plasma produced from a gas including at least one of CO, CO₂, and CH₄. The gas including at least one of CO, CO₂, and CH₄ (hereinafter also referred to as a carbon-containing gas) preferably includes a rare gas or H₂ as a main component and a small amount of a carbon-containing gas, although it may be a carbon-containing gas alone. The plasma may be produced by a capacitive coupling method or the like.

<Gas Barrier Layer B>

The gas barrier layer according to the present invention only has to include at least one gas barrier layer A as described above. In order to improve the gas barrier properties, the gas barrier layer according to the present invention preferably further includes another gas barrier layer B. In particular, the gas barrier B is more preferably provided adjacent to the gas barrier layer A.

In the present invention, the gas barrier layer B is a gas barrier layer having gas barrier properties and a composition different from that of the gas barrier layer A described above. As used herein, the term “a composition different from that of the gas barrier layer A” means, for example, that the gas barrier layer B has a chemical composition of chemical formula (1), in which w, x, y, and z do not simultaneously satisfy mathematical formulae (1) to (4), so that the composition differs from that of the gas barrier layer A.

In the present invention, the gas barrier layer B may be formed by a coating method or a vapor deposition method such as physical vapor deposition (PVD), chemical vapor deposition (CVD), or atomic layer deposition (ALD).

In the present invention, the gas barrier layer B can be formed by a process including applying a coating liquid containing a silicon compound such as a polysilazane compound, drying the coating liquid to forma coating film B, and applying energy to the coating film B. When the gas barrier B is formed adjacent to the gas barrier layer A according to the present invention by such a coating method, the hydrolysis of the gas barrier layer B can be suppressed, so that a synergistic effect can be obtained, by which the gas barrier film can have more improved resistance to heat and moisture. Although the detailed mechanism is not clear, the contact with aluminum in the gas barrier layer A may produce such an effect. The gas barrier layers A and B may be stacked in this order on the substrate. Alternatively, the gas barrier layers B and A may be stacked in this order on the substrate. More preferably, the gas barrier layers B and A are stacked in this order on the substrate. It will be understood that any other layer may be placed between the substrate and the gas barrier layer A or B according to the present invention.

An additive element other than silicon may also be added to the gas barrier layer B being formed by such a coating method.

Examples of the additive element include beryllium (Be), boron (B), magnesium (Mg), aluminum (Al), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf) tantalum (Ta), tungsten (W), rhenium (Re), osmium (Os), iridium (Ir), platinum (Pt), gold (Au), mercury (Hg), thallium (Tl), lead (Pb), and radium (Ra). When aluminum (Al) is added to the gas barrier layer B according to the present invention, the composition of the gas barrier layer B should differ from that of the gas barrier layer A as mentioned above.

Among these elements, boron (B), magnesium (Mg), aluminum (Al), calcium (Ca), titanium (Ti), chromium (Cr), manganese (Mn), iron (Fe), cobalt (Co), copper (Cu), zinc (Zn), gallium (Ga), zirconium (Zr), silver (Ag), and indium (In) are preferred, boron (B), magnesium (Mg), aluminum (Al), calcium (Ca), iron (Fe), gallium (Ga), and indium (In) are more preferred, and boron (B), aluminum (Al), gallium (Ga), and indium (In) are even more preferred. A group 13 element such as boron (B), aluminum (Al), gallium (Ga), or indium (In) has a valence of 3, which is short of valence as compared with silicon with a valence of 4, and therefore can forma film with increased flexibility. As the flexibility is increased, defects are repaired, which allows the gas barrier layer B to be a dense film with improved gas barrier properties. In addition, as the flexibility is increased, oxygen is supplied into the inside of the gas barrier layer B, so that oxidation progresses into the inside of the gas barrier layer B, which allows the gas barrier layer B to have high resistance to oxidation when the film formation is completed. The additive elements may be present alone, or two or more of them may be present in the form of a mixture.

(Coating Method)

In the present invention, the gas barrier layer B can be formed by a coating method including applying a coating liquid containing a silicon compound such as a polysilazane compound.

The silicon compound for use in forming the gas barrier layer B according to the present invention is not limited and may be a nitrogen-containing silicon compound or a nitrogen-free silicon compound. Preferably, the silicon compound is a polysilazane compound. More specifically, the nitrogen-containing silicon compounds and the nitrogen-free silicon compounds listed above for the formation of the gas barrier layer A, and preferred modes thereof may be used as appropriate. Therefore, a duplicate description thereof will be omitted herein.

When the gas barrier layer B is formed by a coating method, the method of preparing the coating liquid containing the silicon compound, the solvent and the catalyst to be used, the method of application, and the method of applying energy (modification) may be similar to those in the formation of the gas barrier layer A. The application of energy is preferably performed by vacuum ultraviolet irradiation. In order to improve the efficiency of the ultraviolet irradiation process, the oxygen concentration is preferably 10 to 10,000 ppm by volume, more preferably 20 to 5,000 ppm by volume, during vacuum ultraviolet irradiation. Taking into account the balance between modification and substrate deformation, the quantity of energy of vacuum ultraviolet light applied to the coating film surface is preferably 1 to 10 J/cm², more preferably 1.5 to 8 J/cm², when the coating film is formed by applying a coating liquid for forming the gas barrier layer B.

As long as the effects of the present invention are not impaired, an additional additive compound may be added in the process of forming the gas barrier layer B by a coating method. Such an additive compound may be, for example, at least one compound selected from the group consisting of water, an alcohol compound, a phenolic compound, a metal alkoxide compound, an alkylamine compound, an alcohol-modified polysiloxane, an alkoxy-modified polysiloxane, and an alkylamino-modified polysiloxane. In particular, at least one compound selected from the group consisting of an alcohol compound, a phenolic compound, a metal alkoxide compound, an alkylamine compound, an alcohol-modified polysiloxane, an alkoxy-modified polysiloxane, and an alkylamino-modified polysiloxane is more preferred.

When the gas barrier layer B is formed by a coating method including the addition of the additive element, the thickness of the coating, the temperature of drying the coating, the application of energy (modification treatment), and other conditions may be similar to those in the formation of the gas barrier layer A, and may be determined with appropriate reference to the above description of the corresponding conditions for the gas barrier layer A.

When the gas barrier layer B is formed by a coating method, the concentration of the solid of the silicon compound in the coating liquid is preferably, but not limited to, 0.1 to 30% by mass, more preferably 0.5 to 20% by mass, even more preferably 1 to 15% by mass, based on the mass of the coating liquid, although it depends on the thickness of the layer or the pot life of the coating liquid.

In the present invention, the thickness of the gas barrier layer B formed by a coating method is preferably 1 to 500 nm, more preferably 5 to 300 nm, even more preferably 10 to 200 nm, although it is not limited as long as the effects of the present invention are not impaired.

(Vapor Phase Deposition)

Alternatively to the coating method, the gas barrier layer B according to the present invention can be formed by vapor phase deposition such as physical vapor deposition, sputtering, atomic layer deposition, or chemical vapor deposition.

When the gas barrier layers B and A are stacked in this order on the substrate, defects in the gas barrier layer B formed by vapor deposition can be efficiently repaired, so that a synergistic effect can be obtained for a significant improvement of the gas barrier properties of the gas barrier film, which is more preferred. This would be an effect produced by excimer light that passes through the gas barrier layer A and directly modifies the interface itself between the gas barrier layers A and B (cleavage of bonds and rearrangement of the structure by recombination) in the excimer modification treatment of the gas barrier layer A.

Hereinafter, the vapor deposition will be described in detail.

Physical vapor deposition (PVD) is a method of depositing a thin film of the desired material, such as a carbon film, on the surface of a material from a vapor phase by a physical technique. Examples include sputtering (DC sputtering, RF sputtering, ion beam sputtering, and magnetron sputtering), vacuum deposition, and ion plating.

Sputtering is a process in which a rare gas element (generally, argon) is ionized by applying a high voltage and allowed to collide with a target placed in a vacuum chamber, so that atoms are sputtered from the surface of the target and deposited on a substrate. In this case, reactive sputtering may also be used, in which nitrogen or oxygen gas is allowed to flow in a chamber so that the element sputtered from the target by argon gas is allowed to react with nitrogen or oxygen to form an inorganic layer.

Atomic layer deposition (ALD) is a process using the chemical adsorption or reaction of two or more low-energy gases on or with the surface of a substrate. Sputtering or CVD, which uses high-energy particles, can cause the formed thin film to have pinholes or to be damaged. In contrast, this process, which uses two or more low-energy gases, is advantageous in that it is less likely to cause pinholes or damages and can form a high-density, monoatomic film (JP 2003-347042 A, JP 2004-535514 W, and WO 2004/105149 A).

Chemical vapor deposition (CVD) is a process in which a raw material gas containing the component for the desired thin film is supplied onto a substrate and subjected to a chemical reaction in the vapor phase or at the surface of the substrate so that a film is deposited on the substrate. There are methods in which a plasma or the like is generated to activate the chemical reaction. Examples of such methods include thermal CVD, catalytic chemical vapor deposition, photo-CVD, vacuum plasma CVD, atmospheric pressure plasma CVD, and other known CVD methods. As a non-limiting example, plasma CVD such as vacuum plasma CVD or atmospheric pressure plasma CVD is preferably used in view of deposition rate and process area.

For example, silicon oxide can be produced using a silicon compound as a raw material compound and using oxygen as a decomposing gas. This is because highly active charged particles and active radicals are present at high densities in the plasma space so that multi-stage chemical reactions are accelerated to a very high rate in the plasma space, which allows the element in the plasma space to be converted to a thermodynamically-stable compound in a very short time.

Hereinafter, the process of producing the gas barrier layer B according to the present invention will be described with reference to an example where a thin film is formed by plasma CVD using a roll-to-roll vacuum deposition apparatus (with opposed rolls).

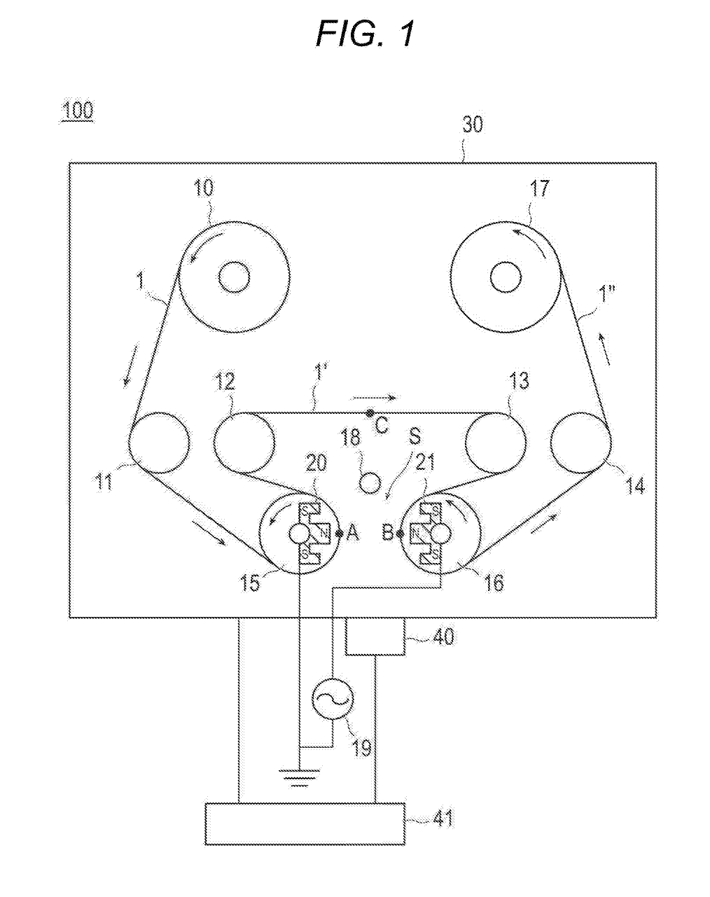

FIG. 1 is a schematic diagram showing the configuration of an example of the deposition apparatus.

As shown in FIG. 1, the deposition apparatus 100 includes an unwinding roll 10, feed rolls 11 to 14, first and second deposition rolls 15 and 16, a winding roll 17, a gas supply pipe 18, a plasma generating power source 19, magnetic field generators 20 and 21, a vacuum chamber 30, a vacuum pump 40, and a controller 41.

The unwinding roll 10, feed rolls 11 to 14, first and second deposition rolls 15 and 16, and winding roll 17 are housed in the vacuum chamber 30.

The unwinding roll 10 is configured to feed a substrate 1 from a roll to the feed roll 11, in which the roll has been formed by winding the substrate 1 and mounted in advance. The unwinding roll 10 is a cylindrical roll extending in a direction perpendicular to the plane of paper, which is configured to feed the substrate 1 from the roll on the unwinding roll 10 to the feed roll 11 by rotating counterclockwise (see the arrow in FIG. 1) along with a driving motor (not shown). The substrate 1 is preferably a film or sheet made of a resin or a composite material containing a resin.

The feed rolls 11 to 14 are cylindrical rolls each configured to be rotatable about the rotation axis substantially parallel to that of the unwinding roll 10. The feed roll 11 is configured to feed the substrate 1 from the unwinding roll 10 to the deposition roll 15 while applying a suitable tension to the substrate 1. The feed rolls 12 and 13 are each configured to feed the substrate 1′ from the deposition roll 15 to the deposition roll 16 while applying a suitable tension to the substrate 1′, in which the substrate 1′ has a film deposited at the deposition roll 15. The feed roll 14 is configured to feed the substrate 1″ from the deposition roll 16 to the winding roll 17 while applying a suitable tension to the substrate 1″, in which the substrate 1″ has a film deposited at the deposition roll 16.

The first and second deposition rolls 15 and 16 are a pair of rolls that each have a rotation axis substantially parallel to that of the unwinding roll 10 and are opposed to each other and placed apart from each other with a given distance. In the example shown in FIG. 1, the distance between the first and second deposition rolls 15 and 16 is the length between points A and B. The first and second deposition rolls 15 and 16 are discharge electrodes made of a conductive material and insulated from each other. The material and structure of the first and second deposition rolls 15 and 16 may be appropriately selected so as to achieve the desired function as an electrode. The magnetic field generators 20 and 21 are installed inside the first and second deposition rolls 15 and 16, respectively. A high-frequency voltage for generating a plasma is applied from the plasma generating power source 19 to the first and second deposition rolls 15 and 16. Therefore, an electric field is formed in the deposition space S between the first and second rolls 15 and 16, which generates a discharge plasma of the deposition gas supplied from the gas supply pipe 18.

The winding roll 17 has a rotation axis substantially parallel to that of the unwinding roll 10 and is configured to wind the substrate 1″ into a roll and hold the roll. The winding roll 17 is configured to wind the substrate 1″ by rotating counterclockwise (see the arrow in FIG. 1) along with a driving motor (not shown).

The substrate 1 is fed from the unwinding roll 10 by the rotation of each of the feed rolls 11 to 14 and the first and second deposition rolls 15 and 16, while a suitable tension is kept on the substrate 1 by allowing the substrate 1 to run around the feed rolls 11 to 14 and the first and second deposition rolls 15 and 16 between the unwinding roll 10 and the winding roll 17. Note that the arrows indicate the directions in which the substrate 1, 1′, and 1″ are fed, respectively. The rate at which the substrates 1, 1′, and 1″ are fed (e.g., the feed rate at point C in FIG. 1) is appropriately controlled depending on the type of the raw material gas and the pressure in the vacuum chamber 30. The feed rate is preferably 0.1 to 100 m/min, more preferably 0.5 to 20 m/min. The feed rate is controlled by controlling the speed of rotation of the driving motors for the unwinding roll 10 and the winding roll 17 by means of the controller 41.

When this deposition apparatus is used, the process of forming the gas barrier film may also be performed by feeding the substrates 1, 1′, and 1″ in directions (hereinafter referred to as backward directions) opposite to the directions indicated by the arrows in FIG. 1 (hereinafter referred to as forward directions). Specifically, the controller 41 operates in such a way that a roll of the substrate 1″ wound by the winding roll 17 is used and the driving motors for the unwinding roll 10 and the winding roll 17 rotate in a direction opposite to that mentioned above. In this control mode, the substrate 1″ is fed in the backward direction from the winding roll 17 by the rotation of each of the feed rolls 11 to 14 and the first and second deposition rolls 15 and 16, while a suitable tension is kept on the substrate 1″ by allowing the substrate 1″ to run around the feed rolls 11 to 14 and the first and second deposition rolls 15 and 16 between the winding roll 17 and the unwinding roll 10.

The gas supply pipe 18 is configured to supply a deposition gas such as a raw material gas for plasma CVD into the vacuum chamber 30. The gas supply pipe 18 has a tubular shape extending in the same direction as that of the rotation axes of the first and second deposition rolls 15 and 16 and placed above the deposition space S. The gas supply pipe 18 is configured to supply the deposition gas to the deposition space S from openings formed at a plurality of sites.

For example, an organosilicon compound, which contains silicon, may be used as the raw material gas. Examples of the organosilicon compound include hexamethyldisiloxane (hereinafter also simply referred to as “HMDSO”), 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, octamethylcyclotetrasiloxane, dimethyldisilazane, trimethyldisilazane, tetramethyldisilazane, pentamethyldisilazane, and hexamethyldisilazane. Among these organosilicon compounds, HMDSO is preferably used in view of easy handling of the compound and high gas barrier properties of the resulting gas barrier film. Two or more of these organosilicon compounds may also be used in combination. The raw material gas may also contain a monosilane in addition to the organosilicon compound.

Besides the raw material gas, a reactive gas may also be used as a deposition gas. A gas capable of reacting with the raw material gas to form an inorganic compound such as an oxide or a nitride is selected as a reactive gas. For example, oxygen or ozone gas may be used as a reactive gas for forming an oxide thin film. Two or more of these reactive gases may be used in combination. In view of gas barrier properties, the ratio of the supplied amount of the deposition gas to that of the reactive gas is preferably, but not limited to, 0.04 to 0.2, more preferably 0.06 to 0.15.

A carrier gas may also be used as a deposition gas to supply the raw material gas into the vacuum chamber 30. A gas for electric discharge may also be used as a deposition gas to form a plasma. For example, a rare gas such as argon and hydrogen or nitrogen may be used as the carrier gas and the gas for electric discharge.

The magnetic field generators 20 and 21 are components configured to form a magnetic field in the deposition space S between the first and second deposition rolls 15 and 16. The magnetic field generators 20 and 21 do not follow the rotation of the first and second deposition rolls 15 and 16 and are housed at predetermined positions.

The vacuum chamber 30 is configured to hermetically house the unwinding roll 10, feed rolls 11 to 14, first and second deposition rolls 15 and 16, and winding roll 17 and to maintain a reduced-pressure state. The pressure (degree of vacuum) in the vacuum chamber 30 can be appropriately controlled depending on the type of the raw material gas or the like. The pressure in the deposition space S is preferably 0.1 to 50 Pa. When the plasma CVD is low-pressure plasma CVD, the pressure is generally 0.1 to 100 Pa for the purpose of controlling vapor-phase reactions.

The vacuum pump 40 is communicably connected to the controller 41 and is configured to appropriately control the pressure in the vacuum chamber 30 in response to an instruction from the controller 41.

The controller 41 is configured to control each component of the deposition apparatus 100. The controller 41 is connected to the driving motors for the unwinding roll 10 and the winding roll 17 and configured to control the substrate 1 feed rate by controlling the rotating speed of these driving motors. The substrate 1 feed direction is also changed by controlling the direction of rotation of the driving motors.

The controller 41 is also communicably connected to a deposition gas supply mechanism (not shown) and configured to control the supply rate of each component of the deposition gas.

The controller 41 is also communicably connected to the plasma generating power source 19 and configured to control the output voltage and output frequency of the plasma generating power source 19.

The controller 41 is further communicably connected to the vacuum pump 40 and configured to control the vacuum pump 40 in such a way that a certain reduced-pressure atmosphere is held in the vacuum chamber 30.

The controller 41 includes a central processing unit (CPU), a hard disk drive (HDD), a random access memory (RAM), and a read only memory (ROM).

Software programs including written procedures for controlling each component of the deposition apparatus 100 and performing the method of producing the gas barrier film are stored on the HDD. When the deposition apparatus 100 is turned on, the software programs are loaded into the RAM and sequentially executed by the CPU. Various data and parameters for use in the execution of the software programs by the CPU are also stored in the ROM.

When formed using the above deposition apparatus, the gas barrier layer B according to the present invention is a film including silicon, oxygen, and carbon. In addition, the gas barrier layer has a substantially continuous carbon distribution curve, which shows the relationship between the distance in the thickness direction from the surface of the gas barrier layer and the ratio of the amount of carbon atoms to the total amount of silicon, oxygen, and carbon atoms, in which the distribution curve has at least one extreme value. The composition of the gas barrier layer B should be determined so as to satisfy these conditions, so that the resulting gas barrier layer B can have sufficient gas barrier properties. The relationship between the composition and gas barrier properties of the gas barrier layer B obtained with the above deposition apparatus and the carbon distribution curve of the gas barrier layer B are well known in detail. Therefore, a detailed description thereof will be omitted.

In the present invention, the thickness of the gas barrier layer B formed by the preferred mode of plasma CVD is preferably 20 to 1,000 nm, more preferably 50 to 500 nm, although it is not limited as long as the effects of the present invention are not impaired.

The gas barrier film of the present invention may further include any of layers having various functions.

<<Anchor Coat Layer>>

To improve the adhesion between the gas barrier layer and the substrate, an anchor coat layer may be formed on the surface of the substrate where the gas barrier layer according to the present invention (gas barrier layer A or B) is to be formed.

An anchor coat agent may be used to form the anchor coat layer. Examples of the anchor coat agent include polyester resin, isocyanate resin, urethane resin, acrylic resin, ethylene vinylalcohol resin, vinyl-modified resin, epoxy resin, modified styrene resin, modified silicon resin, and alkyl titanate, which may be used alone or in combination of two or more.

A conventionally known additive may also be added to these anchor coat agents. The anchor coat agent may be applied to a support by a known method such as roll coating, gravure coating, knife coating, dip coating, or spray coating, and then the solvent, diluent, or the like may be removed by drying, so that an anchor coating can be obtained. The anchor coat agent is preferably applied in an amount of 0.1 to 5.0 g/m² (dry state).

Alternatively, the anchor coat layer may be formed by a gas phase method such as physical vapor deposition or chemical vapor deposition. For example, as described in JP 2008-142941 A, an inorganic film composed mainly of silicon oxide may be formed in order to improve adhesion or the like. Alternatively, as described in JP 2004-314626 A, an anchor coat layer for controlling the composition of an inorganic thin film may be formed, so that the anchor coat layer can block, to some extent, gas generated from the substrate side when an inorganic thin film is formed thereon by a gas phase method.

The thickness of the anchor coat layer is preferably, but not limited to, about 0.5 to about 10 μm.

<<Smooth Layer (Underlayer or Primer Layer)>>

The gas barrier film of the present invention may also have a smooth layer between the substrate and the gas barrier layer A or B. The smooth layer used in the present invention is formed to planarize the rough surface of a transparent resin film support having projections or the like or to planarize a transparent inorganic compound layer by filling in projections and depressions or pinholes, which are formed on or in the transparent inorganic compound layer due to projections on the transparent resin film support. The materials, methods, and other conditions disclosed in paragraphs [0233] to [0248] of JP 2013-52561 A may be appropriately used as for the material and method for forming the smooth layer, its surface roughness, its thickness, and the like.

<<Bleed-Out Layer>>

The gas barrier film of the present invention may also have a bleed-out preventing layer on the surface of the substrate opposite to its surface on which the smooth layer is formed.

On the surface of the substrate opposite to its smooth layer-bearing surface, the bleed-out preventing layer is provided to suppress a phenomenon in which an unreacted oligomer and the like migrate from the smooth layer-bearing film to the surface in the process of heating the smooth layer-bearing film so that the contact surface is polluted with the unreacted oligomer and the like. Basically, the bleed-out preventing layer may have the same composition as that of the smooth layer as long as it has the function mentioned above.

The materials, methods, and other conditions disclosed in paragraphs [0249] to [0262] of JP 2013-52561 A may be appropriately used as for the material and method for forming the bleed-out preventing layer, its thickness, and the like.

{Electronic Device}

Another embodiment of the present invention provides an electronic device having the gas barrier film of the present invention.

The gas barrier film of the present invention is preferably used in devices whose performance can be degraded by chemical components (such as oxygen, water, nitrogen oxide, sulfur oxide, and ozone) in the air. Examples of such devices include electronic devices such as organic EL devices, liquid crystal display devices (LCDs), thin film transistors, touch panels, electronic paper, and photovoltaic cells (PVs). For more efficient achievement of advantageous effect of the present invention, the gas barrier film of the present invention is preferably used in organic EL devices or photovoltaic cells, more preferably in organic EL devices.

The gas barrier film of the present invention may also be used to seal devices. Specifically, a device itself may be used as a support, and the gas barrier film of the present invention may be provided on the surface of the device. The device may be covered with a protective layer before the gas barrier film is provided thereon.

The gas barrier film of the present invention may also be used as a substrate for devices or as a sealing film for use in a solid sealing method. The solid sealing method is a process that includes forming a protective layer on a device, then stacking an adhesive layer and the gas barrier film thereon, and curing the stack. Examples of the adhesive include, but are not limited to, thermosetting epoxy resin and photo-curable acrylate resin.

<<Organic EL Device>>

The gas barrier film of the present invention may be used in organic EL devices, for example, as described in JP 2007-30387 A.

<<Liquid Crystal Display Device>>

A reflective liquid crystal display includes a lower substrate, a reflective electrode, a lower alignment film, a liquid crystal layer, an upper alignment film, a transparent electrode, an upper substrate, a λ/4 plate, and a polarizing film, which are arranged in this order from the lower side. The gas barrier film of the present invention may be used as the transparent electrode substrate and the upper substrate. In the case of a color display, a color filter layer is preferably further provided between the reflective electrode and the lower alignment film or between the upper alignment film and the transparent electrode. A transmissive liquid crystal display includes a backlight, a polarizing plate, a λ/4 plate, a lower transparent electrode, a lower alignment film, a liquid crystal layer, an upper alignment film, an upper transparent electrode, an upper substrate, a λ/4 plate, and a polarizing film, which are arranged in this order from the lower side. In the case of a color display, a color filter layer is preferably further provided between the lower transparent electrode and the lower alignment film or between the upper alignment film and the transparent electrode. The type of the liquid crystal cell is more preferably, but not limited to, twisted nematic (TN), super twisted nematic (STN), hybrid aligned nematic (HAN), vertically alignment (VA), electrically controlled birefringence (ECB), optically compensated bend (OCB), in-plane switching (IPS), or continuous pinwheel alignment (CPA).

<<Photovoltaic Cell>

The gas barrier film of the present invention may also be used as a sealing film for a photovoltaic cell device. In this case, sealing with the gas barrier film of the present invention is preferably performed in such a way that the barrier layer is provided on the side close to the photovoltaic cell device. Examples of the photovoltaic cell device, in which the gas barrier film of the present invention is preferably used, include, but are not limited to, single crystal silicon photovoltaic cell devices, polycrystalline silicon photovoltaic cell devices, amorphous silicon photovoltaic cell devices of a single junction or tandem structure type, III-V compound semiconductor photovoltaic cell devices such as gallium-indium (GaAs) or indium-phosphorus (InP) photovoltaic cell devices, II-VI compound semiconductor photovoltaic cell devices such as cadmium-tellurium (CdTe) photovoltaic cell devices, I-III-VI compound semiconductor photovoltaic cell devices such as copper-indium-selenium (what is called CIS), copper-indium-gallium-selenium (what is called CIGS), or copper-indium-gallium-selenium-sulfur (what is called CIGSS) photovoltaic cell devices, dye-sensitized photovoltaic cell devices, and organic photovoltaic cell devices. Particularly in the present invention, the photovoltaic cell device is preferably a I-III-VI compound semiconductor photovoltaic cell device such as a copper-indium-selenium (what is called CIS), copper-indium-gallium-selenium (what is called CIGS), or copper-indium-gallium-selenium-sulfur (what is called CIGSS)) photovoltaic cell device.

<<Others>>

Other suitable applications of the gas barrier film of the present invention include the thin film transistor described in JP 10-512104 W, the touch panels described in JP 05-127822 A and JP 2002-48913 A, and the electronic paper described in JP 2000-98326 A.

{Optical Component}

The gas barrier film of the present invention may also be used for an optical component. The optical component may be, for example, a circularly polarizing plate or the like.

<<Circularly Polarizing Plate>>

A circularly polarizing plate may be formed by laminating the gas barrier film of the present invention as a substrate, a λ/4 plate, and a polarizing plate. In this case, they are laminated in such a manner that the slow axis of the λ/4 plate makes an angle of 45° with the absorption axis of the polarizing plate. The polarizing plate to be used preferably has undergone stretching in a direction at 45° to the longitudinal direction (MD), which is preferably, for example, that described in JP 2002-865554 A.

### EXAMPLES

Advantageous effects of the present invention will be described with reference to the examples and comparative examples below. It will be understood that the examples below are not intended to limit the technical scope of the present invention. As used in examples, the term “parts” or “%” means “parts by weight” or “% by weight” unless otherwise specified. In the procedures below, operation and measurement of physical properties and the like are performed under the conditions of room temperature (20 to 25° C.) and a relative humidity of 40 to 50% unless otherwise specified.

<Preparation of Coating Liquids>

[Preparation of Material Dilutions A to H]

Material Dilution A

Material dilution A was obtained by diluting a dibutyl ether solution of 20% by mass perhydropolysilazane (AZ NN120-20 manufactured by AZ Electronic Materials) with dibutyl ether to 5% by mass.

Material Dilution B

Material dilution B was obtained by diluting a dibutyl ether solution of 20% by mass catalyst-added perhydropolysilazane (AZ NAX120-20 manufactured by AZ Electronic Materials) with dibutyl ether to 5% by mass.

The dibutyl ether solution of 20% by mass catalyst-added perhydropolysilazane (AZ NAX120-20) is a dibutyl ether solution containing 1% by mass of N,N,N′,N′-tetramethyl-1,6-diaminohexane as an amine catalyst and 19% by mass of perhydropolysilazane.

Material Dilution C

Material dilution C was obtained by diluting a dibutyl ether solution of 20% by mass catalyst-added perhydropolysilazane (AZ NL120-20 manufactured by AZ Electronic Materials) with dibutyl ether to 5% by mass.

The dibutyl ether solution of 20% by mass catalyst-added perhydropolysilazane (AZ NL120-20) is a dibutyl ether solution containing 1% by mass of a palladium catalyst and 19% by mass of perhydropolysilazane.

Material Dilution D

Material dilution D was obtained by diluting aluminum diisopropylate mono-sec-butyrate (an organic aluminum compound) with dibutyl ether to 5% by mass.

Material Dilution E

Material dilution E was obtained by diluting aluminum sec-butyrate (an organic aluminum compound) with dibutyl ether to 5% by mass.

Material Dilution F

Material dilution F was obtained by diluting aluminum ethylacetoacetate diisopropylate (an organic aluminum compound) with dibutyl ether to 5% by mass.

Material Dilution G

Material dilution G was obtained by diluting aluminum trisethylacetoacetate (an organic aluminum compound) with dibutyl ether to 5% by mass.

Material Dilution H

Material dilution H was obtained by diluting Alumichelate M (an organic aluminum compound, manufactured by Kawaken Fine Chemicals Co., Ltd.) with dibutyl ether to 5% by mass.

Alumichelate M includes aluminum 9-octadecenylacetoacetate diisopropylate as a main component.

[Preparation of Coating Liquids 1 to 15]

Material dilutions A to H obtained as described above were mixed in the proportions (mass proportions) shown in Table 1 below. The resulting liquid mixtures were heated to 80° C. with stirring and then kept at 80° C. for 1 hour. The liquid mixtures were then gradually cooled to room temperature to give coating liquids 1 to 15.

TABLE 1

| | |
|---|---|
| Coating | Material dilution No. and |
| liquid | mixing proportion by mass |

| No. | A | B | C | D | E | F | G | H |
|---|---|---|---|---|---|---|---|---|
| 1 | 70 | 30 | | | | | | |
| 2 | 60 | 40 | | | | | | |
| 3 | 70 | | 30 | | | | | |
| 4 | 50 | 20 | | 30 | | | | |
| 5 | 45 | | 15 | 40 | | | | |
| 6 | 37 | 13 | | 50 | | | | |
| 7 | 30 | 10 | | 60 | | | | |
| 8 | 45 | 15 | | | 40 | | | |
| 9 | 35 | 15 | | | 50 | | | |
| 10 | 55 | 20 | | | | 25 | | |
| 11 | 45 | 20 | | | | 35 | | |
| 12 | 37 | | 13 | | | 50 | | |
| 13 | 30 | 10 | | | | 60 | | |
| 14 | 35 | 10 | | | | | 45 | |
| 15 | 30 | 15 | | | | | | 55 |

<Preparation of Gas Barrier Films 1 to 17>

A double-side hard-coated, 125-μm-thick, PET film (KB-FILM (trademark) 125G1SBF manufactured by KIMOTO CO., LTD.) was used as a substrate.

According to the coating liquid type, dry thickness, and excimer treatment conditions shown in Table 2, gas barrier films 1 to 17 having a single gas barrier layer A (examples) or a comparative gas barrier layer (comparative examples) on the substrate were prepared using coating liquids 1 to 15 prepared as described above. In order to adjust each dry thickness, each coating liquid was appropriately diluted as needed with dibutyl ether.

<Measurement of Elemental Ratios in the Composition of Gas Barrier Layer>

Using the instrument and the measurement conditions shown below, the composition profile in the thickness direction was analyzed for the gas barrier layer of each of gas barrier films 1 to 17 prepared. The w, x, y, and z values were then calculated for the gas barrier layer of each film based on the analysis. The y value was the maximum value obtained by performing the measurement three times over the entire thickness of the gas barrier layer. The w, x, and z values were the values measured at the time when the maximum y value was obtained and at the point where the y value was the maximum. The same applies hereinafter. Table 2 below shows the results of each case.

XPS Analysis Conditions

Instrument: QuanteraSXM (manufactured by ULVAC-PHI, Inc.)

X-ray source: monochromatic Al-Kα

Measurement region: Si2p, C1s, N1s, O1s, Al

Sputtering ion: Ar (2 keV)

Depth profile: The measurement is repeated after 1 minute sputtering.

A single measurement corresponds to an about 5-nm-thick part of a SiO₂ thin film standard sample.

Quantification

The background was determined by the Shirley method, and the quantification from the resulting peak area was performed using a relative sensibility coefficient method.

Data processing: MultiPak (manufactured by ULVAC-PHI, Inc.)

The gas barrier layer A according to the present invention and the comparative gas barrier layer in the comparative examples were each the uppermost layer, which was affected by water adsorbed on the surface or by contamination with organic materials. Therefore, the first measurement data were excluded. The hard coat layer of the substrate was adjacent to the gas barrier layer A and the comparative gas barrier layer in the comparative examples. Therefore, it was determined from the continuity of data whether or not the composition of the hard coat layer of the substrate had an influence on the measurement at a point on the boundary between the gas barrier layer and the hard coat layer. When it was determined that the composition of the hard coat layer of the substrate had an influence, the corresponding measurement point was excluded. In this case, since the elemental ratio z of carbon to silicon in the hard coat layer of the substrate is 100 or more, the boundary between the hard coat layer of the substrate and the gas barrier layer A or the comparative gas barrier layer in the comparative examples can be clearly identified from the z value. Therefore, the measurement point at which z was 1 or more was excluded based on the decision that the composition of the hard coat layer of the substrate had an influence on the measurement.

<Evaluation of Water-Vapor Gas Barrier Properties and Durability (Storage Stability Against Heat and Moisture)>

Gas barrier films 1 to 17 prepared were measured for water-vapor gas barrier properties and durability after storage at 85° C. and 85% RH (high-temperature and high-humidity) for 100 hours.

More specifically, each gas barrier film alone was stored in an environment at 85° C. and 85% RH in such a way that both sides of the film were exposed to the storage environment. After stored for 100 hours, each film was dried for 24 hours in an environment at 25° C. and 50% RH.

Before and after the storage, the water-vapor transmission rate of each gas barrier film was measured with a water-vapor transmission rate testing system (PERMATRAN (trade name) manufactured by MOCON Inc.) in an atmosphere at 38° C. and 100% RH. Table 2 below shows the results of each case. The expression “<0.01” is used when the measured value is lower than the lower limit of measurement for the testing system (0.01 g/m²/24 h).

In the present invention, the water-vapor transmission rate is preferably 0.10 g/m²/24 h or less, more preferably 0.07 g/m²/24 h or less, before and after storage at 85° C. and 85% RH (storage under hot and humid or high-temperature and high-humidity conditions).

TABLE 2

| | | | | | | | | | | Water-vapor | | |
|---|---|---|---|---|---|---|---|---|---|---|---|---|
| | | | Excimer treatment conditions | | | | | | | transmission rate | | |
| Gas | | Dry | Stage | Oxygen | | | | | | Before hot | After hot | |
| barrier | Coating | thick- | temper- | concentration | | Elemental ratios in composition | | | | and humid | and humid | |
| film | liquid | ness | ature | (ppm by | Energy | w | x | y | z | storage | storage | |
| No. | No. | (nm) | (° C.) | volume) | (J/cm²) | (Al/Si) | (O/Si) | (N/Si) | (C/Si) | (g/m²/24 h) | (g/m²/24 h) | Note |
| 1 | 1 | 150 | 80 | 1000 | 3.0 | 0.00 | 0.60 | 0.60 | 0.00 | <0.01 | 1.10 | Comparative |
| | | | | | | | | | | | | example |
| 2 | 3 | 150 | 80 | 1000 | 3.0 | 0.00 | 0.62 | 0.55 | 0.00 | <0.01 | 1.20 | Comparative |
| | | | | | | | | | | | | example |
| 3 | 4 | 150 | 80 | 1000 | 3.0 | 0.08 | 2.19 | 0.15 | 0.00 | 0.08 | 0.08 | Inventive example |
| 4 | 5 | 150 | 80 | 1000 | 3.0 | 0.13 | 2.12 | 0.09 | 0.00 | 0.08 | 0.08 | Inventive example |
| 5 | 6 | 150 | 80 | 1000 | 3.0 | 0.19 | 2.28 | 0.08 | 0.00 | 0.10 | 0.10 | Inventive example |
| 6 | 7 | 150 | 80 | 1000 | 3.0 | 0.28 | 2.42 | 0.04 | 0.05 | 0.35 | 0.35 | Comparative |
| | | | | | | | | | | | | example |
| 7 | 8 | 150 | 80 | 1000 | 3.0 | 0.11 | 2.17 | 0.12 | 0.00 | 0.07 | 0.07 | Inventive example |
| 8 | 9 | 150 | 80 | 1000 | 3.0 | 0.15 | 2.23 | 0.07 | 0.00 | 0.08 | 0.08 | Inventive example |
| 9 | 10 | 150 | 80 | 1000 | 3.0 | 0.05 | 1.78 | 0.32 | 0.06 | 0.04 | 1.10 | Comparative |
| | | | | | | | | | | | | example |
| 10 | 11 | 150 | 80 | 1000 | 3.0 | 0.08 | 1.96 | 0.17 | 0.08 | 0.10 | 0.10 | Inventive example |
| 11 | 12 | 150 | 80 | 1000 | 3.0 | 0.15 | 2.18 | 0.08 | 0.10 | 0.07 | 0.07 | Inventive example |
| 12 | 12 | 150 | 80 | 30 | 5.0 | 0.15 | 2.22 | 0.08 | 0.03 | 0.03 | 0.03 | Inventive example |
| 13 | 12 | 150 | 80 | 30 | 3.0 | 0.15 | 1.85 | 0.23 | 0.26 | 0.45 | 0.45 | Comparative |
| | | | | | | | | | | | | example |
| 14 | 12 | 150 | 80 | 30 | 4.0 | 0.15 | 2.15 | 0.12 | 0.15 | 0.09 | 0.09 | Inventive example |
| 15 | 13 | 150 | 80 | 1000 | 3.0 | 0.23 | 1.83 | 0.04 | 0.30 | 0.60 | 0.60 | Comparative |
| | | | | | | | | | | | | example |
| 16 | 14 | 150 | 80 | 1000 | 3.0 | 0.10 | 1.87 | 0.13 | 0.25 | 0.50 | 0.50 | Comparative |
| | | | | | | | | | | | | example |
| 17 | 15 | 150 | 80 | 1000 | 3.0 | 0.10 | 1.84 | 0.13 | 0.82 | 0.80 | 0.80 | Comparative |
| | | | | | | | | | | | | example |

Table 2 shows that gas barrier films according to the present invention have high gas barrier properties and show no degradation of gas barrier properties before and after storage under hot and humid conditions, specifically, that gas barrier films according to the present invention exhibit gas barrier properties even after storage at 85° C. and 85% RH (storage under harsh, high-temperature, high-humidity conditions) and thus have durability.

<Preparation of Gas Barrier Films 18 to 24>

[Formation of Gas Barrier Layer B]

A double-side hard-coated, 125-μm-thick, PET film (KB-FILM (trademark) 125G1SBF manufactured by KIMOTO CO., LTD.) was used as a substrate.

Coating liquid 2 obtained as described above was applied to the substrate in such a way that a coating with a dry thickness of 110 nm would be formed, and then dried at 80° C. for 2 minute. Subsequently, the coating was subjected to an excimer irradiation treatment. The irradiation conditions were a stage temperature of 80° C., an oxygen concentration of 1,000 ppm, and an energy quantity of 5.0 J/cm². A gas barrier layer B was obtained in this way.

The resulting gas barrier film having only the gas barrier layer B is named gas barrier film 18.

[Formation of Gas Barrier Layer A]

Using to the coating liquid, dry thickness, and excimer treatment conditions shown in Table 3, a gas barrier layer A (examples) or a comparative gas barrier layer (comparative examples) was formed on the gas barrier layer B obtained as described above, so that gas barrier films 19 to 24 were obtained. In order to adjust the dry thickness, the coating liquid was appropriately diluted as needed with dibutyl ether.

Under the same measurement conditions as those shown above, the composition profile in the thickness direction was analyzed for the gas barrier layer A (examples) or the comparative gas barrier layer (comparative examples) of each gas barrier film, except for gas barrier film 18. The w, x, y, and z values were then calculated based on the analysis. Table 3 below shows the results of each case. In the XPS analysis and the data processing, the boundary between the gas barrier layer A or the comparative gas barrier layer and the gas barrier layer B was handled as follows. The measured composition profile in the thickness direction was compared with the composition profile in the thickness direction of the sample having only the gas barrier layer B (No. 18). Based on the comparison, a certain measurement point was assumed to be on the surface of the gas barrier layer B. A measurement point adjacent to the gas barrier layer A (examples) or the comparative gas barrier layer (comparative examples) was excluded when determined as being affected by the composition of the gas barrier layer B from the data on the measurement point assumed to be on the surface of the gas barrier layer B.

Under the same measurement conditions as those shown above, gas barrier films 18 to 24 prepared were measured for water-vapor barrier properties before (initial) and after storage at 85° C. and 85% RH (high temperature and high humidity) for 100 hours. Table 3 below shows the results of each case.

TABLE 3

| | | | | | | | | | | Water-vapor | | |
|---|---|---|---|---|---|---|---|---|---|---|---|---|
| | | | Excimer treatment conditions | | | | | | | transmission rate | | |
| | | Dry | | Oxygen | | | | | | Before hot | After hot | |
| Gas | Coating | thick- | Stage | concentration | | Elemental ratios in composition | | | | and humid | and humid | |
| barrier | liquid | ness | temperature | (ppm by | Energy | w | x | y | z | storage | storage | |
| film No. | No. | (nm) | (° C.) | volume) | (J/cm²) | (Al/Si) | (O/Si) | (N/Si) | (C/Si) | (g/m²/24 h) | (g/m²/24 h) | Note |
| 18 | Without second | | | | | | | | | <0.01 | 1.05 | Comparative |
| | layer | | | | | | | | | | | example |
| 19 | 1 | 150 | 80 | 1000 | 3.0 | 0.00 | 0.07 | 0.79 | 0.00 | <0.01 | 0.70 | Comparative |
| | | | | | | | | | | | | example |
| 20 | 5 | 100 | 80 | 1000 | 3.0 | 0.13 | 2.21 | 0.08 | 0.00 | <0.01 | <0.01 | Inventive |
| | | | | | | | | | | | | example |
| 21 | 10 | 150 | 80 | 1000 | 3.0 | 0.05 | 1.05 | 0.42 | 0.06 | <0.01 | 0.25 | Comparative |
| | | | | | | | | | | | | example |
| 22 | 12 | 150 | 80 | 1000 | 3.0 | 0.14 | 2.18 | 0.08 | 0.04 | <0.01 | <0.01 | Inventive |
| | | | | | | | | | | | | example |
| 23 | 12 | 50 | 80 | 1000 | 3.0 | 0.15 | 2.20 | 0.07 | 0.00 | <0.01 | <0.01 | Inventive |
| | | | | | | | | | | | | example |
| 24 | 13 | 100 | 80 | 1000 | 3.0 | 0.23 | 1.86 | 0.03 | 0.28 | <0.01 | 0.60 | Comparative |
| | | | | | | | | | | | | example |

Table 3 shows that gas barrier films according to the present invention with a two-gas-barrier-layer structure have good gas barrier properties, show no degradation of gas barrier properties before and after storage under hot and humid conditions, and exhibit good gas barrier properties even after storage under harsh conditions such as 85° C. and 85% RH.

<Preparation of Gas Barrier Films 25 to 31>

[Formation of Gas Barrier Layer B]

A double-side hard-coated, 125-μm-thick, PET film (KB-FILM (trademark) 125G1SBF manufactured by KIMOTO CO., LTD.) was used as a substrate.

A gas barrier layer B was formed on the substrate by performing a deposition process once under the conditions shown below using the apparatus shown in FIG. 1 having a deposition unit including opposed deposition rolls.

Feed rate: 0.5 m/min

Raw material gas (HMDSO) supply rate: 50 sccm

Oxygen gas supply rate: 500 sccm

Degree of vacuum: 1.5 Pa

Applied power: 0.8 kW

Power frequency: 70 kHz

Thickness: 250 nm

The resulting gas barrier film having only the gas barrier layer B is named gas barrier film 25.

[Formation of Gas Barrier Layer A]

Using to the coating liquid, dry thickness, and excimer treatment conditions shown in Table 4, a gas barrier layer A (examples) or a comparative gas barrier layer (comparative examples) was formed on the gas barrier layer B obtained as described above, so that gas barrier films 26 to 31 were obtained. In order to adjust the dry thickness, the coating liquid was appropriately diluted as needed with dibutyl ether.

Under the same measurement conditions as those shown above, the composition profile in the thickness direction was analyzed for the gas barrier layer A (examples) or the comparative gas barrier layer (comparative examples) of each gas barrier film, except for gas barrier film 25. The w, x, y, and z values were then calculated based on the analysis. Table 4 below shows the results of each case. In the XPS analysis and the data processing, the boundary between the gas barrier layer A or the comparative gas barrier layer and the gas barrier layer B was handled as follows. The measured composition profile in the thickness direction was compared with the composition profile in the thickness direction of the sample having only the gas barrier layer B (No. 25). Based on the comparison, a certain measurement point was assumed to be on the surface of the gas barrier layer B. A measurement point adjacent to the gas barrier layer A (examples) or the comparative gas barrier layer (comparative examples) was excluded when determined as being affected by the composition of the gas barrier layer B from the data on the measurement point assumed to be on the surface of the gas barrier layer B.

<Evaluation of Corrosion Points by Ca Evaluation Test>

A Ca evaluation test was performed on samples before and after storage at 85° C. and 85% RH for 100 hours with respect to gas barrier films 25 to 31 prepared.

The sample after storage at 85° C. and 85% RH for 100 hours is a sample of each gas barrier film having undergone a process in which the sample is stored in an environment at 85° C. and 85% RH for 100 hours in such a way that both sides of the sample are exposed to the storage environment and then the sample is returned to room temperature, room humidity conditions (about 20° C. and 50%). The sample before storage is a sample of each gas barrier film having undergone storage under room temperature, room humidity conditions (about 20° C. and 50%) after the preparation.

More specifically, the samples prepared as described above for evaluation by a Ca corrosion test were stored at a high temperature of 85° C. and a high humidity of 85% RH for 24 hours using a thermo-hygrostat oven (Yamato Humidic Chember IG47M). After the storage for 24 hours, a digital image with 1,000×1,000 pixels was taken of a central 10 mm×10 mm area of the Ca-deposited part of the evaluation sample. In the analysis of the image, the number of corrosion points per 10 mm×10 mm was counted. Table 4 below shows the results of each case.

(Preparation of the Evaluation Samples for the Ca Corrosion Test)

Using a vacuum deposition system JEE-400 (manufactured by JEOL Ltd.), metallic calcium (grains), which corrodes by reacting with water, was vapor-deposited with a thickness of 80 nm through a mask on a 12 mm×12 mm area of the surface of the gas barrier layer of the gas barrier film prepared. Subsequently, the mask was removed while the vacuum state was maintained, and then metallic aluminum (3-5 mm φ, grains), which is impermeable to water vapor, was vapor-deposited for temporary sealing over the entire one-side surface of the sheet. Subsequently, the vacuum was released, and the sheet was quickly transferred to a dry nitrogen gas atmosphere. A 0.2-mm-thick quartz glass sheet was bonded with an ultraviolet-curable resin (manufactured by Nagase ChemteX Corporation) to the surface of the deposited metallic aluminum for temporary sealing. The ultraviolet-curable resin was cured by ultraviolet irradiation for full sealing, so that the evaluation sample for the Ca corrosion test was obtained.

The term “planar corrosion” describes the sample in which the corrosion of Ca is not in the form of dots but in the form of a plane (with a continuous corroded region and a corrosion area ratio of 10% or more). The gas barrier properties are more degraded in the case of planer corrosion than in the case of dot-like corrosion.

TABLE 4

| | | | | | | | | | | Number (/10 mm | |
|---|---|---|---|---|---|---|---|---|---|---|---|
| | | | | | | | | | | square) of | |
| | | | | | | | | | | corrosion | |
| | | | | | | | | | | points in Ca | |
| | | | | | | | | | | test for | |
| | | | Excimer treatment conditions | | | | | | | evaluation of | |
| Gas | Coating | Dry | Stage | Oxygen | | Elemental ratios in composition | | | | water-vapor | |
| barrier | liquid | thickness | temperature | concentration | Energy | w | x | y | z | barrier | |
| film No. | No. | (nm) | (° C.) | (ppm by volume) | (J/cm²) | (Al/Si) | (O/Si) | (N/Si) | (C/Si) | properties | Note |
| 25 | Without second | | | | | | | | | 250 | Comparative |
| | layer | | | | | | | | | | example |
| 26 | 1 | 150 | 80 | 1000 | 3.0 | 0.00 | 0.10 | 0.77 | 0.00 | Planar | Comparative |
| | | | | | | | | | | corrosion | example |
| 27 | 6 | 75 | 80 | 1000 | 3.0 | 0.19 | 2.30 | 0.07 | 0.00 | 0 | Inventive |
| | | | | | | | | | | | example |
| 28 | 7 | 150 | 80 | 1000 | 3.0 | 0.28 | 2.44 | 0.04 | 0.06 | 45 | Comparative |
| | | | | | | | | | | | example |
| 29 | 12 | 30 | 80 | 1000 | 3.0 | 0.15 | 2.22 | 0.07 | 0.00 | 0 | Inventive |
| | | | | | | | | | | | example |
| 30 | 15 | 30 | 80 | 1000 | 3.0 | 0.10 | 2.19 | 0.12 | 0.09 | 5 | Inventive |
| | | | | | | | | | | | example |
| 31 | 15 | 75 | 80 | 1000 | 3.0 | 0.10 | 1.95 | 0.18 | 0.51 | 60 | Inventive |
| | | | | | | | | | | | example |

It has been found from Table 4 that in the gas barrier film of the present invention with the two-gas-barrier-layer structure, the gas barrier layer A can efficiently repair defects in the first gas barrier layer B (such as continuous cracks in the thickness direction) and is still effective in repairing defects even after storage under hot and humid conditions.

The present application claims the benefit of priority to Japanese Patent Application No. 2013-143025 filed on Jul. 8, 2013, the disclosure of which is incorporated herein by reference in its entirety.

1. A gas barrier film comprising:
a substrate; and
at least one gas barrier layer on the substrate, wherein
the gas barrier layer comprises at least one gas barrier layer A having a chemical composition of chemical formula (1),
[Chem. 1]
SiAl_{w}OₓN_{y}C_{z} (1)
wherein w, x, y, and z are elemental ratios of aluminum to silicon, oxygen to silicon, nitrogen to silicon, and carbon to silicon, respectively, measured in a thickness direction of the gas barrier layer,
y is a maximum value of the elemental ratio of nitrogen to silicon measured in the thickness direction of the gas barrier layer and satisfies mathematical formula (1), and
w, x, and z satisfy mathematical formulae (2) to (4)
[Math. 1]
0.05≦y≦0.20 mathematical formula (1)
0.07≦w≦0.20 mathematical formula (2)
1.90≦x≦2.40 mathematical formula (3)
0.00≦z≦0.20 mathematical formula (4)
respectively, when measured at a point where the elemental ratio of nitrogen to silicon is the maximum value.

2. The gas barrier film according to claim 1, wherein the gas barrier layer further comprises another gas barrier layer B, and the gas barrier layers A and B are adjacent to each other.

3. The gas barrier film according to claim 2, wherein the gas barrier layer B is a product formed by applying a coating liquid containing a polysilazane compound, drying the coating liquid to form a coating film B, and applying energy to the coating film B.

4. The gas barrier film according to claim 3, wherein the energy is applied by vacuum ultraviolet irradiation.

5. The gas barrier film according to claim 2, wherein the gas barrier layer B is a product formed by vapor deposition.

6. The gas barrier film according to claim 1, wherein in chemical formula (1), y satisfies mathematical formula (5), and w, x, and z satisfy mathematical formulae (6) to (8), respectively, when measured at a point where the elemental ratio of nitrogen to silicon is the maximum value.
[Math. 2]
0.05≦y≦0.15 mathematical formula (5)
0.10≦w≦0.15 mathematical formula (6)
2.00≦x≦2.25 mathematical formula (7)
0.00≦z≦0.10 mathematical formula (8)

7. The gas barrier film according to claim 1, wherein the gas barrier layer A is a product formed by applying a coating liquid containing a compound or compounds including silicon, aluminum, oxygen, nitrogen, and carbon, drying the coating liquid to form a coating film A, and applying energy to the coating film A.

8. The gas barrier film according to claim 7, wherein the energy is applied by vacuum ultraviolet irradiation.

9. The gas barrier film according to claim 7, wherein the coating liquid containing a compound or compounds including silicon, aluminum, oxygen, nitrogen, and carbon is a coating liquid containing a polysilazane compound and an organic aluminum compound.

10. An electronic device comprising the gas barrier film according to claim 1.

11. The gas barrier film according to claim 2, wherein in chemical formula (1), y satisfies mathematical formula (5), and w, x, and z satisfy mathematical formulae (6) to (8), respectively, when measured at a point where the elemental ratio of nitrogen to silicon is the maximum value.
[Math. 2]
0.05≦y≦0.15 mathematical formula (5)
0.10≦w≦0.15 mathematical formula (6)
2.00≦x≦2.25 mathematical formula (7)
0.00≦z≦0.10 mathematical formula (8)

12. The gas barrier film according to claim 2, wherein the gas barrier layer A is a product formed by applying a coating liquid containing a compound or compounds including silicon, aluminum, oxygen, nitrogen, and carbon, drying the coating liquid to form a coating film A, and applying energy to the coating film A.

13. An electronic device comprising the gas barrier film according to claim 2.

14. The gas barrier film according to claim 3, wherein in chemical formula (1), y satisfies mathematical formula (5), and w, x, and z satisfy mathematical formulae (6) to (8), respectively, when measured at a point where the elemental ratio of nitrogen to silicon is the maximum value.
[Math. 2]
0.05≦y≦0.15 mathematical formula (5)
0.10≦w≦0.15 mathematical formula (6)
2.00≦x≦2.25 mathematical formula (7)
0.00≦z≦0.10 mathematical formula (8)

15. The gas barrier film according to claim 3, wherein the gas barrier layer A is a product formed by applying a coating liquid containing a compound or compounds including silicon, aluminum, oxygen, nitrogen, and carbon, drying the coating liquid to form a coating film A, and applying energy to the coating film A.

16. An electronic device comprising the gas barrier film according to claim 3.

17. The gas barrier film according to claim 4, wherein in chemical formula (1), y satisfies mathematical formula (5), and w, x, and z satisfy mathematical formulae (6) to (8), respectively, when measured at a point where the elemental ratio of nitrogen to silicon is the maximum value.
[Math. 2]
0.05≦y≦0.15 mathematical formula (5)
0.10≦w=0.15 mathematical formula (6)
2.00≦x≦2.25 mathematical formula (7)
0.00≦z≦0.10 mathematical formula (8)

18. The gas barrier film according to claim 4, wherein the gas barrier layer A is a product formed by applying a coating liquid containing a compound or compounds including silicon, aluminum, oxygen, nitrogen, and carbon, drying the coating liquid to form a coating film A, and applying energy to the coating film A.

19. An electronic device comprising the gas barrier film according to claim 4.

20. The gas barrier film according to claim 5, wherein in chemical formula (1), y satisfies mathematical formula (5), and w, x, and z satisfy mathematical formulae (6) to (8), respectively, when measured at a point where the elemental ratio of nitrogen to silicon is the maximum value.
[Math.2]
0.05≦y≦0.15 mathematical formula(5)
0.10≦w≦0.15 mathematical formula(6)
2.00≦x≦2.25 mathematical formula(7)
0.00≦z≦0.10 mathematical formula(8)
